(19) United States
(12) Patent Application Publication
(10) Pub. No.: US 2026/0040523 A1
(43) Pub. Date: Feb. 5, 2026

(54) SEMICONDUCTOR DEVICE

(71) Applicant: Semiconductor Energy Laboratory Co., Ltd., Atsugi-shi, Kanagawa-ken (JP)

(72) Inventors: Kazuma FURUTANI, Atsugi (JP); Yuto YAKUBO, Atsugi (JP); Kouhei TOYOTAKA, Isehara (JP)

(21) Appl. No.: 19/114,537

(22) PCT Filed: Oct. 5, 2023
(86) PCT No.: PCT/IB2023/059989

§ 371 Date: Mar. 24, 2025

(30) Foreign Application Priority Data
Oct. 13, 2022 (JP) 2022-164532
Oct. 21, 2022 (JP) 2022-168765

(51) Int. Cl. H10B 12/00; G11C 11/405

(52) U.S. Cl. CPC H10B 12/00; G11C 11/405

(57) ABSTRACT

A semiconductor device with a novel configuration is provided. The semiconductor device includes a first element layer including a bit line driver circuit; a second element layer including a first switch circuit, a first memory cell, and a first wiring provided between the first switch circuit and the first memory cell; and a third element layer including a second switch circuit, a second memory cell, and a second wiring provided between the second switch circuit and the second memory cell. The first switch circuit has a function of establishing a non-conduction state between the first wiring and a third wiring in data write operation or read operation of the second memory cell. The second switch circuit has a function of establishing a non-conduction state between the second wiring and the third wiring in data write operation or read operation of the first memory cell.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device (a memory device), a driving method thereof, and a manufacturing method thereof.

### BACKGROUND ART

In recent years, research and development have been actively conducted on configurations where a plurality of dies (e.g., silicon dies) provided with circuits having different functions, such as SRAM (Static Random Access Memory) cells or DRAM (Dynamic Random Access Memory) cells, are three-dimensionally stacked (e.g., Non-Patent Document 1 and Non-Patent Document 2).

In addition, in recent years, technology development of semiconductor devices that can hold electric charge according to data has advanced with the use of transistors using oxide semiconductors in channel formation regions (hereinafter such transistors are referred to as OS transistors). A layer including an OS transistor can be stacked and provided over a die (an element layer) including a transistor that uses silicon in a channel formation region (hereinafter such a transistor is referred to as a Si transistor). Patent Document 1 discloses a configuration where an element layer including a plurality of OS transistors are three-dimensionally stacked and provided over an element layer including a Si transistor.

### REFERENCE

### Patent Document

### Patent Document 1

PCT International Publication No. WO2020/152522

### Non-Patent Document

[Non-Patent Document 1]

W. Gomes et al., ISSCC Dig. Tech. Papers, pp. 42-43, 2022.

### Non-Patent Document 2

M. Park et al., ISSCC Dig. Tech. Papers, pp. 444-445, 2022.

### SUMMARY OF THE INVENTION

### Problems to be Solved by the Invention

A configuration where an element layer including a plurality of OS transistors is provided over an element layer including a Si transistor is effective in achieving higher integration of a circuit, such as improving memory density. However, in a configuration where higher integration is achieved by increasing the number of stacks of element layers including OS transistors, a wiring for electrically connecting a circuit included in an upper element layer and a circuit included in a lower element layer becomes long. For example, a wiring provided between a bit line driver circuit provided in the element layer including a Si transistor and a memory cell provided in the upper element layer including an OS transistor might become long. Consequently, parasitic capacitance and parasitic resistance of the wiring for performing data writing or reading between the bit line driver circuit and the memory cell increase, which might result in the decrease in operating speed or loss in data reliability.

One object of one embodiment of the present invention is to provide a novel semiconductor device or the like. Another object of one embodiment of the present invention is to provide a semiconductor device or the like with a novel configuration that is excellent in reducing power consumption. Another object of one embodiment of the present invention is to provide a semiconductor device or the like with higher operating speed and a novel configuration. Another object of one embodiment of the present invention is to provide a semiconductor device or the like with high data reliability and a novel configuration.

Note that the objects of one embodiment of the present invention are not limited to the objects above. The objects listed above do not preclude the presence of other objects.

Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device that includes a first element layer including a bit line driver circuit; a second element layer including a first switch circuit, a first memory cell, and a first wiring provided between the first switch circuit and the first memory cell; and a third element layer including a second switch circuit, a second memory cell, and a second wiring provided between the second switch circuit and the second memory cell. The second element layer is provided over the first element layer to overlap the first element layer. The third element layer is provided over the second element layer to overlap the second element layer. The second element layer and the third element layer are provided with a third wiring electrically connected to the bit line driver circuit. The bit line driver circuit is electrically connected to the first switch circuit and the second switch circuit through the third wiring. The first switch circuit has a function of establishing a non-conduction state between the first wiring and the third wiring in data write operation or read operation of the second memory cell. The second switch circuit a function of establishing a non-conduction state between the second wiring and the third wiring in data write operation or read operation of the first memory cell.

In the above embodiment of the present invention, in the semiconductor device, the second element layer and the third element layer are each preferably provided with a transistor where a semiconductor layer including a channel formation region is an oxide semiconductor.

In the above embodiment of the present invention, in the semiconductor device, the oxide semiconductor preferably includes In, Ga, and Zn.

In the above embodiment of the present invention, in the semiconductor device, the first element layer is preferably provided with a transistor where a semiconductor layer including a channel formation region is silicon.

In the above embodiment of the present invention, in the semiconductor device, it is preferable that the first switch circuit have a function of pre-charging a potential of the first wiring and that the second switch circuit have a function of pre-charging a potential of the second wiring.

In the above embodiment of the present invention, in the semiconductor device, it is preferable that the first element layer include an arithmetic circuit having a function of performing arithmetic processing based on data read to the bit line driver circuit and that the arithmetic circuit be provided in a region overlapping a region where the first memory cell included in the second element layer and the second memory cell included in the third element layer are provided.

In the above embodiment of the present invention, in the semiconductor device, the first wiring and the second wiring each preferably include a portion provided in the same direction as a direction perpendicular to a substrate surface provided with the first element layer.

One embodiment of the present invention is a semiconductor device that includes a first element layer including a word line driver circuit and a bit line driver circuit; a second element layer including a first switch circuit, a first layer selection circuit, a first memory cell, a first wiring provided between the first switch circuit and the first memory cell, and a second wiring provided between the first layer selection circuit and the first memory cell; and a third element layer including a second switch circuit, a second layer selection circuit, a second memory cell, a third wiring provided between the second switch circuit and the second memory cell, and a fourth wiring provided between the second layer selection circuit and the second memory cell. The second element layer is provided over the first element layer to overlap the first element layer. The third element layer is provided over the second element layer to overlap the second element layer. The second element layer and the third element layer are provided with a fifth wiring electrically connected to the bit line driver circuit and a sixth wiring electrically connected to the word line driver circuit. The bit line driver circuit is electrically connected to the first switch circuit and the second switch circuit through the fifth wiring. The word line driver circuit is electrically connected to the first layer selection circuit and the second layer selection circuit through the sixth wiring. The first switch circuit a function of establishing a non-conduction state between the first wiring and the fifth wiring in data write operation or read operation of the second memory cell. The second switch circuit a function of establishing a non-conduction state between the third wiring and the fifth wiring in data write operation or read operation of the first memory cell. The first layer selection circuit and the second layer selection circuit each have a function of outputting, to the second wiring or the fourth wiring, a signal output from the word line driver circuit.

In the above embodiment of the present invention, in the semiconductor device, the second element layer and the third element layer are each preferably provided with a transistor where a semiconductor layer including a channel formation region is an oxide semiconductor.

In the above embodiment of the present invention, in the semiconductor device, the oxide semiconductor preferably includes In, Ga, and Zn.

In the above embodiment of the present invention, in the semiconductor device, the first element layer is preferably provided with a transistor where a semiconductor layer including a channel formation region is silicon.

In the above embodiment of the present invention, in the semiconductor device, it is preferable that the first switch circuit have a function of pre-charging a potential of the first wiring and that the second switch circuit have a function of pre-charging a potential of the third wiring.

In the above embodiment of the present invention, in the semiconductor device, it is preferable that the first element layer include an arithmetic circuit having a function of performing arithmetic processing based on data read to the bit line driver circuit and that the arithmetic circuit be provided in a region overlapping a region where the first memory cell included in the second element layer and the second memory cell included in the third element layer are provided.

In the above embodiment of the present invention, in the semiconductor device, the first wiring and the third wiring each preferably include a portion provided in the same direction as a direction perpendicular to a substrate surface provided with the first element layer.

Note that other embodiments of the present invention are illustrated in the description of the following embodiments and the drawings. Effect of the Invention

One embodiment of the present invention can provide a novel semiconductor device or the like. Alternatively, one embodiment of the present invention can provide a semiconductor device or the like with a novel configuration that is excellent in reducing power consumption. Alternatively, one embodiment of the present invention can provide a semiconductor device or the like with higher operating speed and a novel configuration.

Alternatively, one embodiment of the present invention can provide a semiconductor device or the like with high data reliability and a novel configuration.

Note that the description of these effects does not preclude the presence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams each illustrating a configuration example of a semiconductor device.

FIG. 2A and FIG. 2B are diagrams each illustrating a configuration example of the semiconductor device.

FIG. 3A and FIG. 3B are diagrams each illustrating a configuration example of the semiconductor device.

FIG. 4 is a diagram illustrating a configuration example of the semiconductor device.

FIG. 5A is a diagram illustrating a configuration example of the semiconductor device, and

FIG. 5B and FIG. 5C are timing charts each showing an operation example of the semiconductor device.

FIG. 6A and FIG. 6B are diagrams each illustrating a configuration example of the semiconductor device.

FIG. 7 is a diagram illustrating a configuration example of the semiconductor device.

FIG. 8A and FIG. 8B are diagrams each illustrating a configuration example of the semiconductor device.

FIG. 9A and FIG. 9B are diagrams each illustrating a configuration example of the semiconductor device.

FIG. 10 is a timing chart showing an operation example of the semiconductor device.

FIG. 11 is a diagram illustrating a configuration example of the semiconductor device.

FIG. 12 is a diagram illustrating a configuration example of the semiconductor device.

FIG. 13 is a diagram illustrating a configuration example of the semiconductor device.

FIG. 14 is a timing chart showing an operation example of the semiconductor device.

FIG. 15A and FIG. 15B are diagrams each illustrating a configuration example of the semiconductor device.

FIG. 16 is a diagram illustrating a configuration example of the semiconductor device.

FIG. 17 is a diagram illustrating a configuration example of the semiconductor device.

FIG. 18A and FIG. 18B are diagrams each illustrating a configuration example of the semiconductor device.

FIG. 19 is a diagram illustrating a configuration example of the semiconductor device.

FIG. 20A to FIG. 20C are diagrams each illustrating a configuration example of the semiconductor device.

FIG. 21 is a diagram illustrating a configuration example of the semiconductor device.

FIG. 22A to FIG. 22D are diagrams each illustrating a configuration example of the semiconductor device.

FIG. 23 is a diagram illustrating a configuration example of the semiconductor device.

FIG. 24A is a diagram illustrating a configuration example of the semiconductor device. FIG. 24B is a diagram illustrating an equivalent circuit of the semiconductor device.

FIG. 25A and FIG. 25B are diagrams each illustrating an example of an electronic component.

FIG. 26A and FIG. 26B are diagrams each illustrating an example of an electronic device, and FIG. 26C to FIG. 26E are diagrams each illustrating an example of a large computer.

FIG. 27 is a diagram illustrating an example of space equipment.

FIG. 28 illustrates an example of a storage system applicable to a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an OFF state (also referred to as a non-conduction state or a cutoff state). Unless otherwise specified, an OFF state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### EMBODIMENT 1

In this embodiment, configuration examples, operation examples, and the like of a semiconductor device that is one embodiment of the present invention will be described.

The semiconductor device described in one embodiment of the present invention has a function of an SoC (System on Chip) where a memory cell array provided across a plurality of element layers, a driver circuit for driving the memory cell array, and the like are closely coupled.

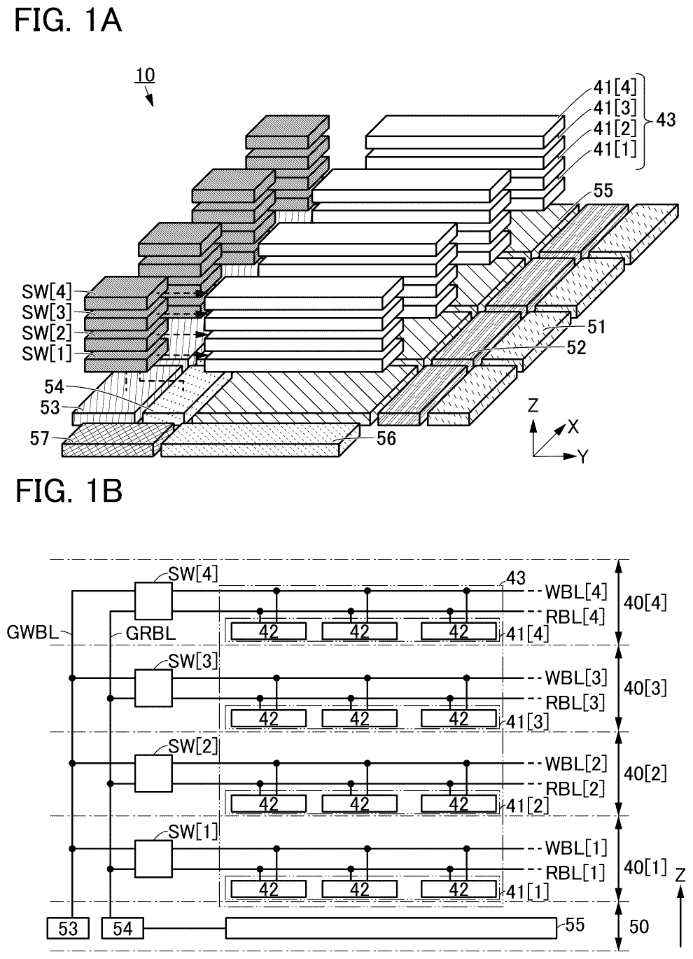

FIG. 1A and FIG. 1B are a schematic diagram and a block diagram, respectively, each illustrating a configuration example of a semiconductor device according to one embodiment of the present invention.

Note that in the schematic diagram and the block diagram illustrated in FIG. 1A, FIG. 1B, and the like, an X direction, a Y direction, and a Z direction are defined to describe the arrangement of components included in the semiconductor device. The X direction, the Y direction, and the Z direction are perpendicular or substantially perpendicular to each other.

In addition, in FIG. 1A, FIG. 1B, and the like, the arrangement of components included in a semiconductor device 10 are separately illustrated for easy understanding. Although components provided in the same layer are preferably formed in the same step, one embodiment of the present invention is not limited thereto. For example, components formed in different steps may be integrated by an attachment technique or the like.

The semiconductor device 10 illustrated in FIG. 1A and FIG. 1B includes other element layers (element layers 40) stacked and provided over an element layer 50. For example, as illustrated in FIG. 1B, the semiconductor device 10 includes four element layers 40 (element layers 40[1] to 40[4], which are illustrated as an example) stacked and provided over the element layer 50.

Note that a first element layer 40 is denoted by the element layer 40[1], a second element layer 40 is denoted by the element layer 40[2], and a third element layer 40 is denoted by the element layer 40[3]. In addition, a k-th (k is an integer greater than or equal to 2) element layer 40 is denoted by an element layer 40[k]. Note that in this embodiment and the like, the “element layer 40” is merely stated in some cases when describing a matter related to all of a plurality of element layers 40 or showing a matter common to the plurality of element layers 40. Similarly, the same applies to a configuration where a reference numeral for describing a plurality of configurations is used.

The element layers 40[1] to 40[4] include OS transistors. The element layers 40[1] to 40[4] including the OS transistors can be stacked and provided over a substrate such as the element layer 50.

Examples of a metal oxide employed for the OS transistor in the element layer 40 include indium oxide, gallium oxide, and zinc oxide. In addition, the metal oxide preferably contains two or three or more selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element Mis preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin, and zinc (also referred to as ITZO). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO).

In addition, the metal oxide employed for the OS transistor may include two or more metal oxide layers with different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and provided over the first metal oxide layer can be suitably used.

Alternatively, a stacked-layer structure or the like of any one selected from indium oxide, indium gallium oxide, and IGZO, and any one selected from IAZO, IAGZO, and ITZO may be used, for example.

Note that the metal oxide employed for the OS transistor preferably has crystallinity. As an oxide semiconductor having crystallinity, a CAAC (c-axis aligned crystalline)-OS, an nc (nanocrystalline)-OS, and the like can be given. When the oxide semiconductor having crystallinity is used, a highly reliable semiconductor device can be provided.

The element layers 40 include memory cell portions 41 (memory cell portions 41[1] to 41[4]) provided for respective layers. The memory cell portions 41 each include a plurality of memory cells 42. A plurality of memory cell portions 41 provided in the element layers 40 form a memory cell array 43.

The memory cell array 43 including the memory cells 42 preferably has a NOSRAM circuit configuration, for example. That is, each of the memory cells 42 is a memory cell having a NOSRAM circuit configuration. NOSRAM (registered trademark) is an abbreviation for “Nonvolatile Oxide Semiconductor Random Access Memory (RAM).” NOSRAM refers to a memory where a memory cell is a two-transistor (2T) or three-transistor (3T) gain cell and a transistor is an OS transistor.

The OS transistor that can be provided in the element layer 40 has extremely low current that flows between a source and a drain in an OFF state, that is, extremely low off-state current. The NOSRAM can be used as a nonvolatile memory by holding electric charge corresponding to data in the memory cell with the use of characteristics of extremely low off-state current. In particular, the NOSRAM is capable of reading retained data without destruction (non-destructive reading), and thus is suitable for arithmetic processing in which only data read operation is repeated many times. Stacking and providing the NOSRAM can increase data capacity; thus, the use of the NOSRAM as a large-scale cache memory, a large-scale main memory, or a large-scale storage memory allows the semiconductor device to have high performance.

The element layers 40 include wirings WBL (wirings WBL[1] to WBL[4]) for data writing of the memory cells 42 and wirings RBL (wirings RBL[1] to RBL[4]) for data reading. In FIG. 1B, the wiring WBL and the wiring RBL provided for the element layer 40[1] are denoted by the wiring WBL[1] and the wiring RBL[1], respectively. The same applies to the wirings WBL[2] to WBL[4] and the wirings RBL[2] to RBL[4]; the wirings WBL[2] to WBL[4] and the wirings RBL[2] to RBL[4] are illustrated as wirings provided for the element layers 40[2] to 40[4], respectively.

The wiring WBL is connected to the memory cell 42. The wiring WBL has a function of a bit line for writing data to the memory cell 42. The wiring RBL is connected to the memory cell 42. The wiring RBL has a function of a bit line for reading data from the memory cell 42.

The element layers 40 include switch circuits SW (switch circuits SW[1] to SW[4]). In FIG. 1B, a switch circuit SW provided in the element layer 40[1] is denoted by the switch circuit SW[1]. The same applies to the switch circuits SW[2] to SW[4]; the switch circuits SW[2] to SW[4] are illustrated as switch circuits provided in the element layers 40[2] to 40[4], respectively. The switch circuits SW each have a function of switching electrical connection between any one of a plurality of wirings WBL (the wirings WBL[1] to WBL[4]) and a wiring GWBL, and electrical connection between any one of a plurality of wirings RBL (the wirings RBL[1] to RBL[4]) and a wiring GRBL.

The wiring GWBL and the wiring GRBL are provided to extend from the element layer 50 to the plurality of element layers 40 in a direction where the element layers 40 are stacked over the element layer 50 (the Z direction). The Z direction is a direction perpendicular to a substrate surface provided with the element layer 50. The wiring GWBL has a function of transmitting, to the switch circuit SW in each layer, a potential corresponding to data output from a write bit line driver circuit 53. The wiring GRBL has a function of transmitting, to a read bit line driver circuit 54 through the switch circuit SW, a potential corresponding to data read from the memory cell 42 included in the element layer 40 to the wiring RBL.

The switch circuit SW includes a plurality of switches that switch electrical connection between the wiring WBL and the wiring GWBL, and electrical connection between the wiring RBL and the wiring GRBL. The plurality of switches can be formed using transistors. The transistors included in the switch circuit SW are preferably OS transistors that can be provided in the element layer 40. With this configuration, when the OS transistors included in the switch circuit SW are set in an OFF state, potentials of the wiring WBL and the wiring RBL can be retained.

The element layer 50 includes elements provided for a silicon substrate or the like. The element layer 50 is provided with Si transistors. For the Si transistors, the use of silicon having high crystallinity, such as single crystal silicon or polycrystalline silicon, is particularly preferable because high field-effect mobility can be achieved and higher-speed operation is possible. The element layer 50 is sometimes referred to as a substrate or a silicon substrate.

The element layer 50 illustrated in FIG. 1B includes write word line driver circuits 51, read word line driver circuits 52, the write bit line driver circuit 53, and the read bit line driver circuit 54, which are illustrated in FIG. 1A. The element layer 50 illustrated in FIG. 1B further includes an arithmetic circuit 55, an arithmetic control circuit 56, and a control circuit 57, which are illustrated in FIG. 1A. High-speed operation is possible because the circuits can be formed using the Si transistors included in the element layer 50.

The write word line driver circuit 51 outputs, to a wiring that functions as a write word line, a signal that controls writing of data to the memory cells 42 provided in the element layer 40. The read word line driver circuit 52 outputs, to a wiring that functions as a read word line, a signal that controls reading of data from the memory cells 42 provided in the element layer 40. The write word line driver circuit 51 and the read word line driver circuit 52 are collectively referred to as a word line driver circuit in some cases.

The write bit line driver circuit 53 outputs, to the wiring GWBL, a potential (a signal) corresponding to data written to the memory cells 42 provided in the element layer 40. The read bit line driver circuit 54 outputs data based on a potential corresponding to data read from the memory cells 42 provided in the element layer 40 to the wiring GRBL through the switch circuit SW. The write bit line driver circuit 53 and the read bit line driver circuit 54 are collectively referred to as a bit line driver circuit in some cases.

The arithmetic circuit 55 has a function of performing arithmetic processing based on data obtained by the read bit line driver circuit 54. The arithmetic control circuit 56 is a circuit for controlling arithmetic operation in the arithmetic circuit 55. The arithmetic circuit 55 includes a plurality of PEs (processing elements), for example. Through parallel processing of product-sum operation, the PEs can perform parallel processing of matrix operation in graphics operation, parallel processing of neural network product-sum operation, parallel processing of floating-point operation in scientific computation, and the like, for example. Note that in this case, the memory cells 42 preferably store weight data used for arithmetic processing. Since the semiconductor device 10 has the function of what is called SoC where the arithmetic circuit 55 performing parallel processing, the memory cells 42 retaining weight data, and the like are closely coupled, a wiring for connecting devices that perform data transfer can be shortened, which inhibits an increase in heat generation and power consumption.

The control circuit 57 has a function of a memory controller that controls the bit line driver circuit and the word line driver circuit. The control circuit 57 may have a function of controlling the arithmetic control circuit 56 and the like. Note that in the semiconductor device 10, the arithmetic circuit 55, the arithmetic control circuit 56, and the control circuit 57 may each have another configuration.

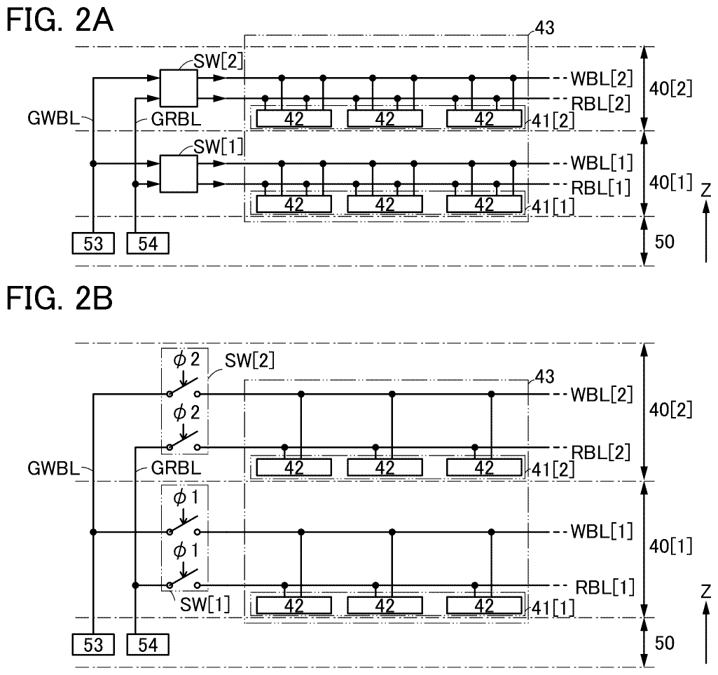

FIG. 2A illustrates the case where the element layers 40 in FIG. 1B are two layers to describe an operation example of the semiconductor device 10. In addition, FIG. 2B illustrates a specific example of circuits included in the switch circuits SW[1] and SW[2] in the configuration of FIG. 2A.

The switch circuit SW[1] illustrated in FIG. 2B includes switches whose ON and OFF states are controlled by a signal φ1. The switch circuit SW[2] illustrated in FIG. 2B includes switches whose ON and OFF states are controlled by a signal φ2. The switches included in the switch circuit SW[1] switch a conduction (ON) state and a non-conduction (OFF) state between the wiring GWBL and the wiring WBL[1] and between the wiring GRBL and the wiring RBL[1]. The switches included in the switch circuit SW[2] switch a conduction (ON) state and a non-conduction (OFF) state between the wiring GWBL and the wiring WBL[2] and between the wiring GRBL and the wiring RBL[2]. In the case where the element layers 40 are three or more layers, switch circuits SW including switches are similarly provided to switch a conduction (ON) state and a non-conduction (OFF) state between the wiring GWBL and the wiring WBL and between the wiring GRBL and the wiring RBL.

The signals φ1 and φ2 are selection signals for selecting any one of the layers in response to data writing or reading to/from the memory cells 42 included in the element layer 40[1] or the element layer 40[2]. For example, in the case of writing or reading data to/from the element layer 40[1], the signal φ1 is set to a signal for making the switches active, that is, for turning on the switches, and a signal supplied to other switch circuits SW, such as the signal φ2, is set to a signal for making the switches inactive, that is, for turning off the switches. Furthermore, in the case of writing or reading data to/from the element layer 40[2], the signal φ2 is set to a signal for making the switches active, that is, for turning on the switches, and a signal supplied to other switch circuits SW, such as the signal φ1, is set to a signal for making the switches inactive, that is, for turning off the switches.

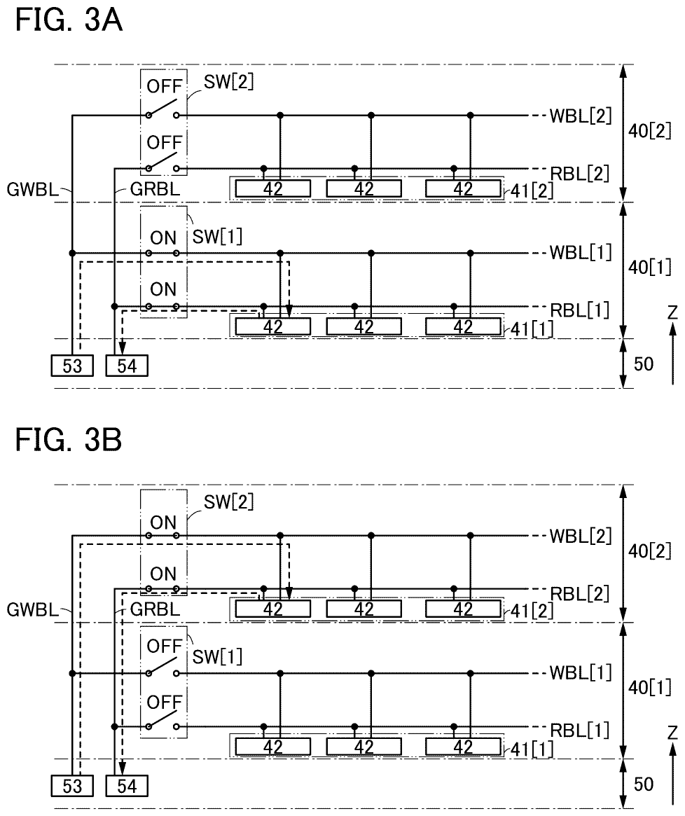

FIG. 3A is a diagram schematically illustrating ON and OFF of the switches included in the switch circuits SW[1] and SW[2] when the memory cells 42 included in the element layer 40[1] are selected to perform data writing or reading. As illustrated in FIG. 3A, by turning on the switches included in the switch circuit SW[1] by the signal φ1 and turning off the switches included in the switch circuit SW[2] by the signal φ2, the memory cells 42 included in the element layer 40[1] can be selected to perform data writing or reading. Note that in FIG. 3A, between the wiring GWBL and the wiring WBL[1] and between the wiring GRBL and the wiring RBL[1], dotted arrows indicate data input/output between the memory cells 42 and bit line driver circuits (the write bit line driver circuit 53 and the read bit line driver circuit 54).

FIG. 3B is a diagram schematically illustrating ON and OFF of the switches included in the switch circuits SW[1] and SW[2] when the memory cells 42 included in the element layer 40[2] are selected to perform data writing or reading. As illustrated in FIG. 3B, by turning on the switches included in the switch circuit SW[2] by the signal φ2 and turning off the switches included in the switch circuit SW[1] by the signal φ1, the memory cells 42 included in the element layer 40[2] can be selected to perform data writing or reading. Note that in FIG. 3B, between the wiring GWBL and the wiring WBL[2] and between the wiring GRBL and the wiring RBL[2], dotted arrows indicate data input/output between the memory cells 42 and bit line driver circuits (the write bit line driver circuit 53 and the read bit line driver circuit 54).

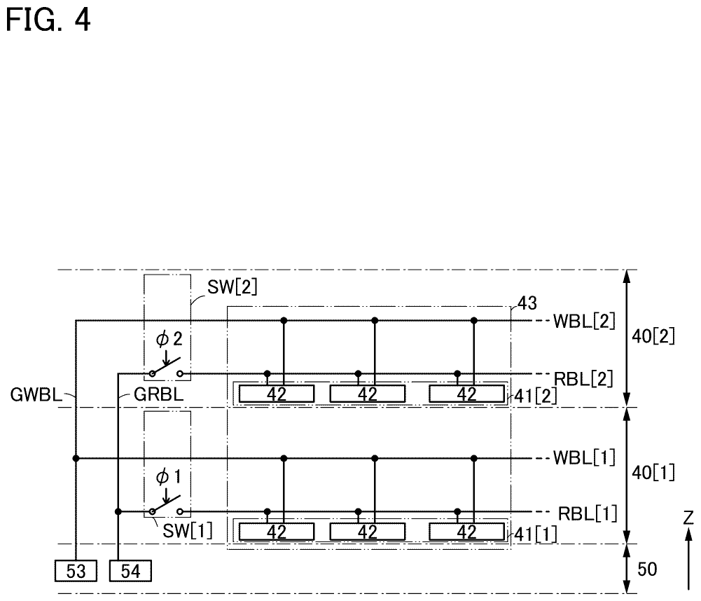

Note that although FIG. 3A and FIG. 3B each illustrate the configuration where the switches of the switch circuits SW are provided between the wiring GWBL and the wiring WBL and between the wiring GRBL and the wiring RBL, another configuration may be employed. For example, as illustrated in FIG. 4, a configuration where the switches between the wiring GWBL and the wirings WBL are omitted may be employed.

In the semiconductor device of one embodiment of the present invention, in a configuration where data is written or read to/from memory cells provided across the plurality of element layers, the switch circuits are provided between the wirings connected to the bit line driver circuits and the wirings connected to the memory cells in the element layers. With this configuration, wirings connected to memory cells in element layers where data is not written or read to/from the memory cells can be electrically separated from wirings connected to memory cells in element layers where data is written or read to/from the memory cells. Thus, in addition to a reduction in power consumption, an increase in density, and an increase in memory capacity due to the use of memory cells including stacked OS transistors, wiring loads of wirings functioning as signal lines can be reduced, which results in higher-speed data reading and writing and higher data reliability.

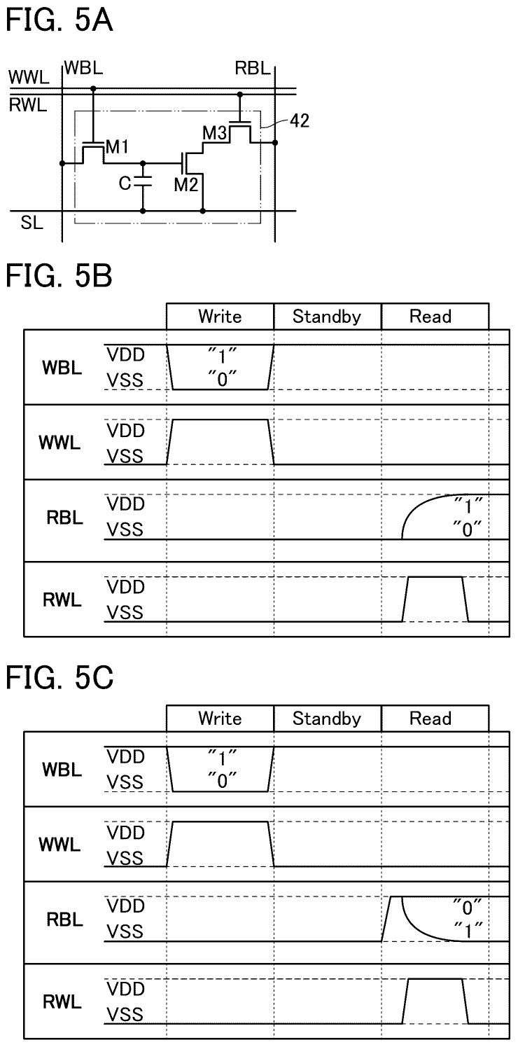

FIG. 5A is a circuit diagram of a NOSRAM applicable to the memory cells 42. In addition, FIG. 5B and FIG. 5C are timing charts for showing operation of the NOSRAM illustrated in FIG. 5A.

FIG. 5A illustrates an example of a circuit configuration of a NOSRAM memory cell applicable to the memory cells illustrated in FIG. 1B and the like. The memory cell 42 illustrated in FIG. 5A includes transistors M1 to M3 and a capacitor C. OS transistors can be used as the transistors M1 to M3. FIG. 5A illustrates a wiring WWL, a wiring RWL, the wiring WBL, the wiring RBL, and a wiring SL that are connected to components included in the memory cell 42. In addition to the function of a capacitor line, the wiring SL can also function as a wiring for applying a potential to a back gate of each of the transistors.

An operation example of the memory cell 42 is described with reference to FIG. 5B. FIG. 5B is a timing chart showing an operation example of the memory cell 42. In write operation (Write), read operation (Read), and a standby state (Standby), VDD is input to each of the wirings as an “H” potential, and VSS is input to each of the wirings as an “L” potential. Note that although each of VDD and VSS is illustrated as the same potential between the wirings, each of VDD and VSS may vary between the wirings.

In the write operation, the wiring WWL selected by the write word line driver circuit 51 is at “H,” and the wiring RWL selected by the read word line driver circuit 52 is at “L.” A potential corresponding to data is input to the wiring WBL selected by the write bit line driver circuit 53 and the switch circuit SW. The wiring RBL selected by the read bit line driver circuit 54 and the switch circuit SW is at “L.” A gate potential of the transistor M2 in the selected memory cell 42 is VDD when data “1” is written, and the gate potential of the transistor M2 in the selected memory cell 42 is VSS when data “0” is written. In the read operation of FIG. 5B, the wiring RBL selected by the read bit line driver circuit 54 and the switch circuit SW is pre-discharged (sometimes simply referred to as discharged) to VSS. Next, the wiring RWL selected by the read word line driver circuit 52 is set to “H.” In the case where the selected memory cell 42 retains the data “1,” large current flows between a source and a drain of the transistor M2 by setting the wiring SL to VDD because VDD is input to a gate of the transistor M2. Thus, the wiring RBL is promptly charged, so that a potential of the wiring RBL is increased. In the case where the selected memory cell 42 retains the data “0,” the transistor M2 passes almost no drain current because VSS is input to the gate of the transistor M2. Thus, the wiring RBL holds discharge voltage (VSS).

Note that in the read operation, the wiring RBL selected by the read bit line driver circuit 54 may be pre-charged to VDD. FIG. 5C illustrates such a case.

In read operation in FIG. 5C, the wiring RBL selected by the read bit line driver circuit 54 is pre-charged to VDD. Next, the wiring RWL selected by the read word line driver circuit 52 is set to “H.” In the case where the selected memory cell 42 retains the data “1,” large current flows between the source and the drain of the transistor M2 by setting the wiring SL to VSS because VDD is input to the gate of the transistor M2. Thus, the wiring RBL is promptly discharged, so that the potential of the wiring RBL is decreased. In the case where the selected memory cell 42 retains the data “0,” the transistor M2 feeds almost no drain current because VSS is input to the gate of the transistor M2. Thus, the wiring RBL holds pre-charge voltage (VDD).

In a standby state, the wiring WWL and the wiring RBL are at “L” during a period other than write operation and the read operation. The transistors M1 and M3 in the memory cell 42 are in an OFF state. Since the transistors M1 to M3 are OS transistors having extremely low off-state current, the memory cell 42 can retain data for a long time by setting the transistor M1 and the transistor M3 in an OFF state. In principle, the memory cell 42 has no limitation on the number of write operation (rewriting) times, data rewriting can be performed at low energy, and no power is consumed for data retention. The semiconductor device 10 can thus include a nonvolatile memory cell with low power consumption.

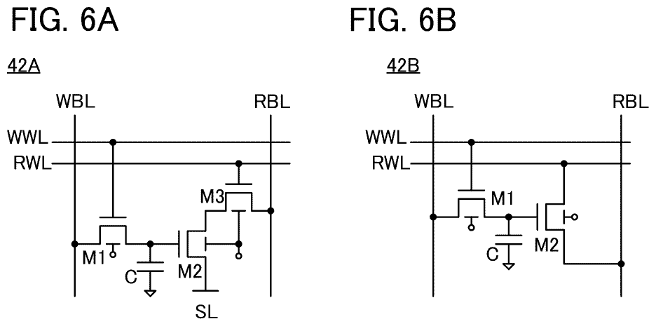

A circuit configuration of the memory cell 42 is not limited to the circuit configuration in FIG. 5A. For example, like a memory cell 42A illustrated in FIG. 6A, the transistors M1 to M3 can each have a back gate. Alternatively, like a memory cell 42B illustrated in FIG. 6B, a configuration where the transistor M3 is omitted may be employed. Alternatively, a configuration where the capacitor C is omitted by using parasitic capacitance, gate capacitance, or the like may be employed.

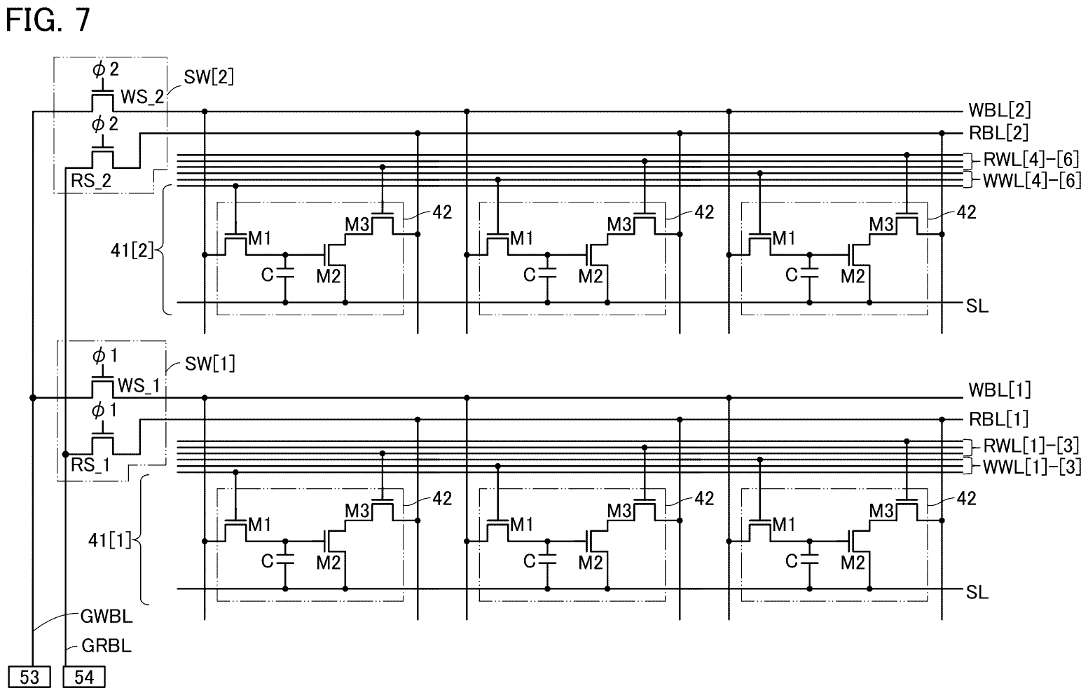

FIG. 7 is a diagram illustrating a configuration of the wirings WWL and RWL that are connected to the memory cells 42 in the element layers when the two element layers 40 illustrated in FIG. 2A or FIG. 2B are used. FIG. 7 illustrates that three memory cells 42 are provided in each of the memory cell portions 41[1] and 41[2]; the memory cell portions 41[1] and 41[2] are provided in the respective element layers 40. FIG. 7 illustrates wirings WWL[1]-[6] that function as write word lines and wirings RWL[1]-[6] that function as read word lines for controlling the memory cells 42 in the memory cell portions 41[1] and 41[2].

FIG. 7 illustrates a circuit diagram of the NOSRAM memory cells illustrated in FIG. 5A. The memory cells 42 included in the memory cell portion 41[1] are connected to the common wirings WBL[1] and RBL[1]. In addition, the three memory cells 42 included in the memory cell portion 41[1] illustrated in FIG. 7 are connected to different wirings WWL[1]-[3] and RWL[1]-[3]. Furthermore, the memory cells 42 included in the memory cell portion 41[2] are connected to the common wirings WBL[2] and RBL[2]. Moreover, the three memory cells 42 included in the memory cell portion 41[2] illustrated in FIG. 7 are connected to different wirings WWL[4]-[6] and RWL[4]-[6].

In FIG. 7, switches included in the switch circuits SW[1] and SW[2] are represented as transistors. Transistors included in the switch circuit SW[1] are denoted by transistors RS_1 and WS_1. The ON and OFF states of the transistors RS_1 and WS_1 are controlled by the signals φ1, so that a conduction state and a non-conduction state between the wiring GWBL and the wiring WBL[1] and between the wiring GRBL and the wiring RBL[1] are controlled. In addition, transistors included in the switch circuit SW[2] are denoted by transistors RS_2 and WS_2. The ON and OFF states of the transistors RS_2 and WS_2 are controlled by the signals φ2, so that a conduction state and a non-conduction state between the wiring GWBL and the wiring WBL[2] and between the wiring GRBL and the wiring RBL[2] are controlled.

Like the transistors included in the memory cells 42, the transistors included in the switch circuits SW[1] and SW[2] can be OS transistors. In the case where the OS transistors are n-channel transistors, the OS transistors function as switches that are turned on when potentials supplied to gates are at an H level and are turned off when the potentials supplied to the gates are at an L level. In addition, since the OS transistors have low off-state current as described above, turning off the transistors allows retention of potentials of the wirings WBL and RBL.

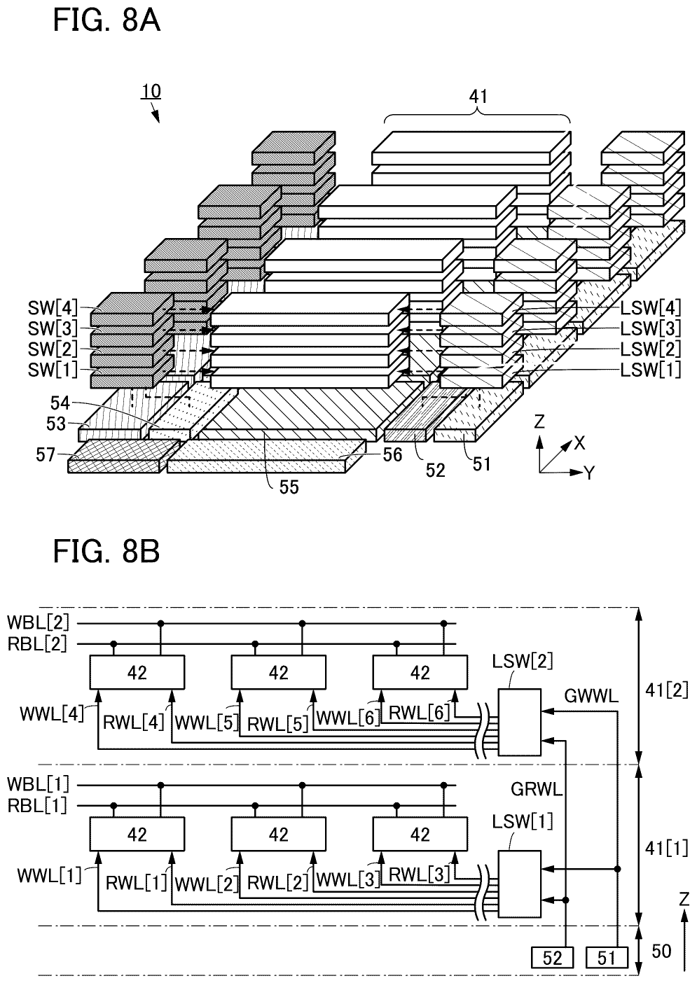

FIG. 8A is a schematic diagram where layer selection circuits LSW[1] to LSW[4] are added to the configuration described in FIG. 1A. When the layer selection circuits LSW are provided, the semiconductor device 10 can supply signals of the write word line driver circuit 51 and the read word line driver circuit 52 to the wirings WWL[1]-[6] and the wirings RWL[1]-[6] based on a signal for selecting a given element layer 40.

FIG. 8B is a diagram illustrating the wirings WWL[1]-[6], the wirings RWL[1]-[6], a wiring GWWL, and a wiring GRWL that are connected to the layer selection circuits LSW[1] and LSW[2] when the layer selection circuits LSW[1] and LSW[2] are employed in the configuration in FIG. 7. The wiring GWWL is a wiring having a function of transmitting signals of the write word line driver circuit 51 to the layer selection circuits LSW in the element layers 40. The wiring GRWL is a wiring having a function of transmitting signals of the read word line driver circuit 52 to the layer selection circuits LSW in the element layers 40.

Signals supplied from the write word line driver circuit 51 through the wiring GWWL, signals supplied from the read word line driver circuit 52 through the wiring GRWL, and signals (e.g., the signals φ1 and φ2) for selecting any one of the element layers 40 are input to the layer selection circuits LSW, and the layer selection circuits LSW output signals supplied to the wirings WWL[1]-[6] and the wirings RWL[1]-[6]. Thus, it is possible to transmit signals from the write word line driver circuit 51 and the read word line driver circuit 52 to the upper element layer 40 with a small number of wirings compared with the wirings WWL[1]-[6] and the wirings RWL[1]-[6] that are included in the element layers 40. Accordingly, as the number of element layers 40 increases, signals of the write word line driver circuit 51 and the read word line driver circuit 52 can be transmitted to the upper element layer 40 with a small number of wirings.

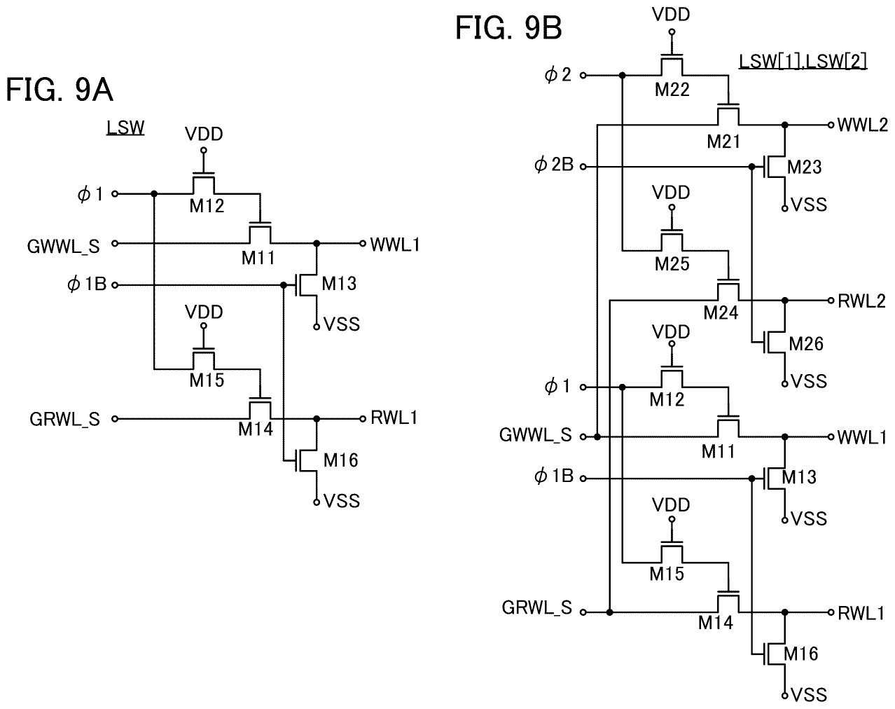

FIG. 9A is a circuit diagram illustrating an example of a circuit configuration applicable to the layer selection circuit LSW. Constant potentials (VDD and VSS), the signal φ1, a signal φ1B (an inverted signal of φ1), a signal GWWL_S from the write word line driver circuit 51, and a signal GRWL_S from the read word line driver circuit 52 are supplied to the layer selection circuit LSW illustrated in FIG. 9A, and the layer selection circuit LSW illustrated in FIG. 9A can generate a signal WWL1 (a signal supplied to the wiring WWL[1]) and a signal RWL1 (a signal supplied to the wiring RWL[1]).

The layer selection circuit LSW illustrated in FIG. 9A includes transistors M11 to M16. As in the memory cells 42, each of the transistors M11 to M16 can be an OS transistor provided in the stacked element layer 40. Thus, the layer selection circuits LSW[1] to LSW[4] in FIG. 8A each including the layer selection circuit LSW can be provided to overlap in the Z direction, as illustrated in FIG. 8A.

FIG. 9B is a circuit diagram illustrating an example of a circuit configuration corresponding to the layer selection circuits LSW[1] and LSW[2] for two layers. As illustrated in FIG. 9B, the layer selection circuits LSW[1] and LSW[2] can generate constant potentials (VDD and VSS), the signal φ1, the signal φ1B, the signal φ2, a signal φ2B (an inverted signal of φ2), the signal GWWL_S from the write word line driver circuit 51, the signal WWL1 (a signal supplied to the wirings WWL[1] to WWL[3]), the signal RWL1 (a signal supplied to the wirings RWL[1] to RWL[3]), a signal WWL2 (a signal supplied to the wirings WWL[4] to WWL[6]), and a signal RWL2 (a signal supplied to the wirings RWL[4] to RWL[6]).

The layer selection circuits LSW[1] and LSW[2] include the transistors M11 to M16 and transistors M21 to M26. As in the memory cells 42, each of the transistors M11 to M16 and M21 to M26 can be an OS transistor provided in the stacked element layers 40[1] to 40[2]. The layer selection circuits LSW[1] and LSW[2] can be provided to overlap in the Z direction.

The number of signals supplied to the wirings WWL[1]-[6] and the wirings RWL[1]-[6] for driving the memory cells 42 provided in different element layers 40 increases according to the number of stacks. A configuration provided with the layer selection circuits LSW can output signals supplied to the wirings WWL and the wirings RWL just by increasing the number of signals for supplying signals for layer selection even when the number of element layers 40 increases. Thus, the semiconductor device 10 can inhibit an increase in the area of the word line driver circuit due to the increase in the number of element layers 40 provided with the memory cells 42. That is, the semiconductor device 10 can increase the number of element layers 40 provided with the memory cells 42 without an increase in area overhead.

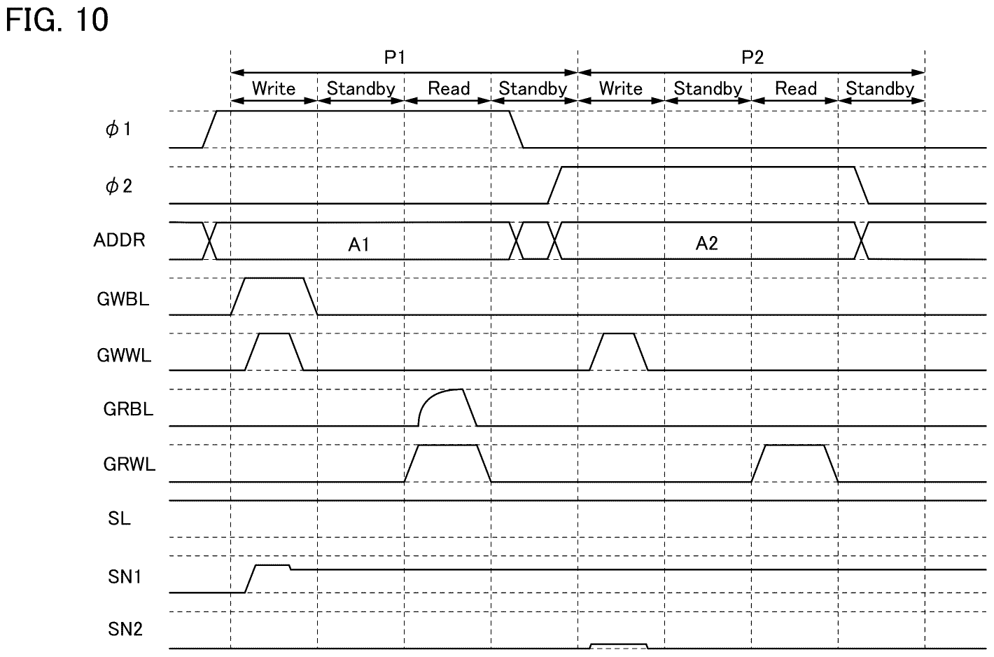

Next, an operation example of the semiconductor device is described with reference to a timing chart shown in FIG. 10.

The operation example shown in FIG. 10 is described based on the write operation and read operation of the memory cell 42 described in FIG. 5B. That is, the wiring SL is set to VDD, and the read operation is performed while discharging the wiring RBL (corresponding to the wiring GRBL) to VSS.

A period P1 is a period during which an address A1 (ADDR) of the memory cell 42 included in the element layer 40[1] is accessed. A period P2 is a period during which an address A2 (ADDR) of the memory cell 42 included in the element layer 40[2] is accessed. In the periods P1 and P2, periods of write operation (Write), read operation (Read), and a standby state (Standby) are provided. In the period during which the element layer 40[1] is accessed, the signal φ1 is set in a selected state (an H level). In the period during which the element layer 40[2] is accessed, the signal φ2 is set in a selected state (an H level).

In FIG. 10, a node that is connected to the gate of the transistor M2 at the address Al of the memory cell 42 included in the element layer 40[1] is denoted by a node SN1. A node that is connected to the gate of the transistor M2 at the address A2 of the memory cell 42 included in the element layer 40[2] is denoted by a node SN2. The nodes SN1 and SN2 are described on the assumption that L-level (VSS) data is written in an initial state.

In addition, in FIG. 10, signals of the wiring GWBL, the wiring GWWL, the wiring GRBL, and the wiring GRWL can be signals supplied to wirings connected to the memory cell 42 accessed in each period through a combination of the signal φ1 and the signal φ2.

For example, in the period P1, a potential of the wiring GWWL that is at an H level is a signal selectively supplied to the wiring WWL[1] connected to the memory cell 42 included in the element layer 40[1] by the signal φ1. In addition, in the period P2, the potential of the wiring GWWL that is at an H level is a signal selectively supplied to the wiring WWL[2] connected to the memory cell 42 included in the element layer 40[2] by the signal φ2.

Furthermore, in the period P1, a potential of the wiring GWBL that is at an H level is a signal selectively supplied to the wiring WBL[1] connected to the memory cell 42 included in the element layer 40[1] by the signal φ1. Moreover, in the period P2, the potential of the wiring GWBL that is at an L level is a signal selectively supplied to the wiring WBL[2] connected to the memory cell 42 included in the element layer 40[2] by the signal φ2.

Furthermore, in the period P1, the potential of the wiring GWBL that varies depending on a potential of data written to the selected memory cell 42 is a signal selectively supplied to the wiring WBL[1] connected to the memory cell 42 included in the element layer 40[1] by the signal φ1. Moreover, in the period P2, the potential of the wiring GWBL that varies depending on the potential of data written to the selected memory cell 42 is a signal selectively supplied to the wiring WBL[2] connected to the memory cell 42 included in the element layer 40[2] by the signal φ2.

Furthermore, in the period P1, a potential of the wiring GRBL that varies depending on the potential retained in the selected memory cell 42 varies depending on a variation in a potential of RBL[1] connected to the memory cell 42 included in the element layer 40[1] selectively by the signal φ1. Moreover, in the period P2, the potential of the wiring GRBL that varies depending on the potential retained in the selected memory cell 42 varies depending on a variation in a potential of RBL[2] connected to the memory cell 42 included in the element layer 40[2] selectively by the signal φ2.

In the period PI during which the address A1 of the memory cell 42 included in the element layer 40[1] is accessed, data “1” is written to a predetermined memory cell 42 in the write operation (Write) while setting the signal φ1 in a selected state (an H level). The wiring GWBL and the wiring GWWL are set to an H level (VDD), and the wiring WBL[1] and the wiring WWL[1] in the element layer 40 selected by the signal φ1 are set to an H level, so that a potential of the node SN1 increases. The potential of the node SN1 slightly varies by the influence of feedthrough or charge injection due to switching of ON and OFF states of the transistor M1 in accordance with falling of the wiring GWWL (a change from VDD to VSS). The increased potential of the node SN1 is retained in and after the standby state (Standby) period. In the read operation (Read), the data “1” is read from the predetermined memory cell 42. By discharging the wiring GRBL, the wiring RBL[1] in the element layer 40 selected by the signal φ1 is discharged. By setting the wiring GRWL to an H level, the wiring RWL[1] in the element layer 40 selected by the signal φ1 is set to an H level. As a result, the wiring RBL[1] is charged, and the wiring GRBL that is connected to the wiring RBL[1] in the element layer 40 selected by the signal φ1 is also charged. After that, it enters the standby state (Standby) period, and the potential of the node SN1 continues to be retained.

In the period P2 during which the address A2 of the memory cell 42 included in the element layer 40[2] is accessed, data “0” is written to a predetermined memory cell 42 in the write operation (Write) while setting the signal φ2 in a selected state (an H level). The wiring GWBL is set to an L level, and the wiring WBL[2] in the element layer 40 selected by the signal φ2 is set to an L level. In addition, the wiring GWWL is set to an H level (VDD), and the wiring WWL[2] in the element layer 40 selected by the signal φ2 is set to an H level. The potential of the node SN2 slightly varies by the influence of rising of the wiring GWWL (a change from VSS to VDD) and feedthrough or charge injection in accordance with falling of the wiring GWWL; however, the potential does not change before and after the write operation (Write) period. The potential of the node SN2 is retained in and after the standby state (Standby) period. In the read operation (Read), the data “O” is read from the predetermined memory cell 42. By discharging the wiring GRBL, the wiring RBL[2] in the element layer 40 selected by the signal φ2 is discharged. By setting the wiring GRWL to an H level, the wiring RWL[2] in the element layer 40 selected by the signal φ2 is set to an H level. As a result, the wiring RBL[2] remains at an L level, and the wiring GRBL that is connected to the wiring RBL[2] in the element layer 40 selected by the signal φ2 also remains at an L level. After that, it enters the standby state (Standby) period, and the potential of the node SN2 continues to be retained.

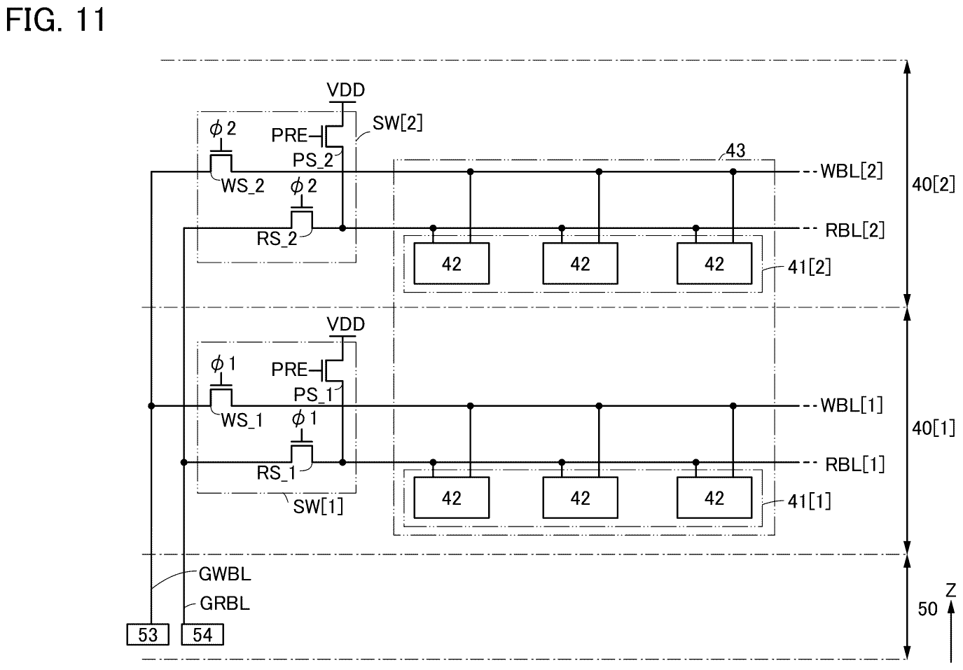

Next, in FIG. 11, a modification example of the switch circuit SW is described. A configuration illustrated in FIG. 11 is a configuration where a transistor PS_1 that is connected to the wiring RBL[1] is added to the switch circuit SW[1] illustrated in FIG. 7 and a transistor PS_2 that is connected to the wiring RBL[2] is added to the switch circuit SW[2] illustrated in FIG. 7. The transistor PS_1 has a function of supplying the potential VDD to the wiring RBL[1] in accordance with control of a pre-charge signal PRE. The transistor PS_2 has a function of supplying the potential VDD to the wiring RBL[2] in accordance with control of the pre-charge signal PRE. With this configuration, when the switch included in the switch circuit SW is in an OFF state, pre-charging can be performed, so that a pre-charge period can be shortened because parasitic capacitance of a wiring to be pre-charged can be reduced. Note that when the pre-charge voltage is VSS, discharging can also be performed.

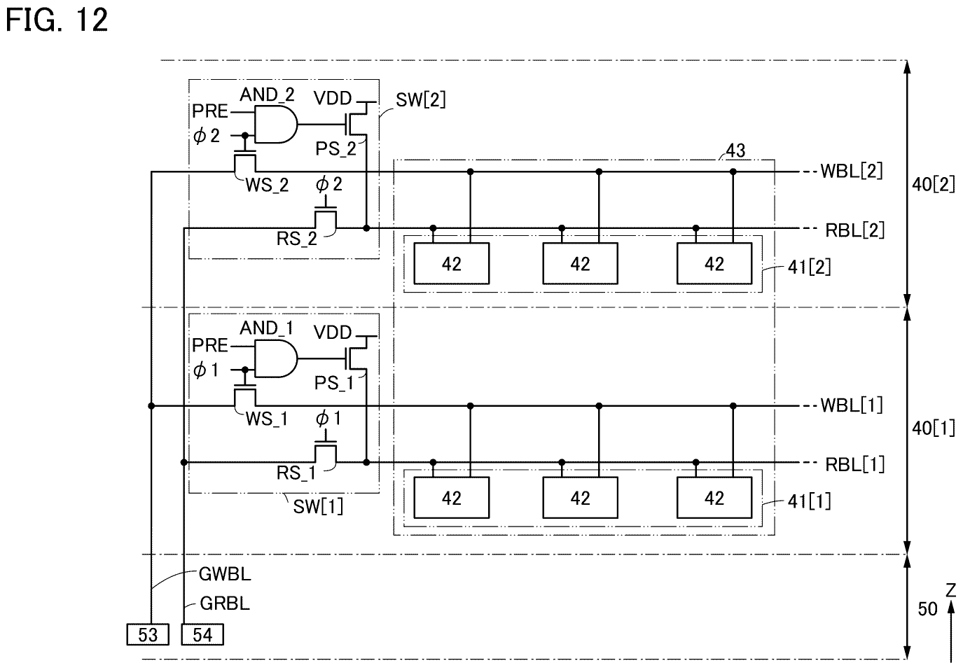

In addition, FIG. 12 illustrates a configuration where AND gates are added, as a modification example of the switch circuit SW that is different from FIG. 11. The signal φ1 for selecting the element layer 40[1] and the pre-charge signal PRE are supplied to an AND gate AND_1. Similarly, the signal φ2 for selecting the element layer 40[2] and the pre-charge signal PRE are supplied to an AND gate AND_2. Thus, pre-charging can be performed when the switch included in the switch circuit SW in the selected element layer 40 is in an ON state and the switch included in the switch circuit SW in the unselected element layer 40 is in an OFF state. Consequently, the wiring RBL that performs pre-charging can be separated from the wiring RBL that does not perform pre-charging, so that parasitic capacitance of a wiring to be pre-charged can be reduced. Accordingly, a pre-charge period can be shortened.

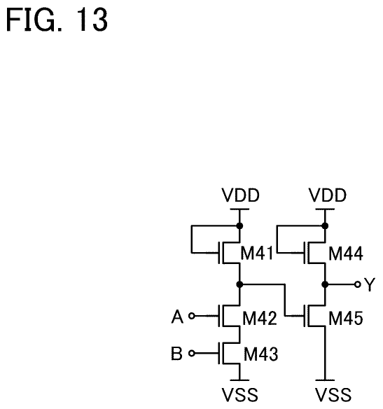

Note that the AND gates AND_1 and AND_2 illustrated in FIG. 12 can be provided in the element layer 40, as illustrated in FIG. 13, when the AND gates AND_1 and AND_2 are formed using OS transistors. An AND gate illustrated in FIG. 13 is formed using transistors M41 to M45 that are n-channel OS transistors. The AND gate illustrated in FIG. 13 can obtain an output signal Y with respect to input signals A and B. The transistors M41 to M45 can function as the AND gate because the input signals A and B can be both at an H level and the output signal can be at an H level.

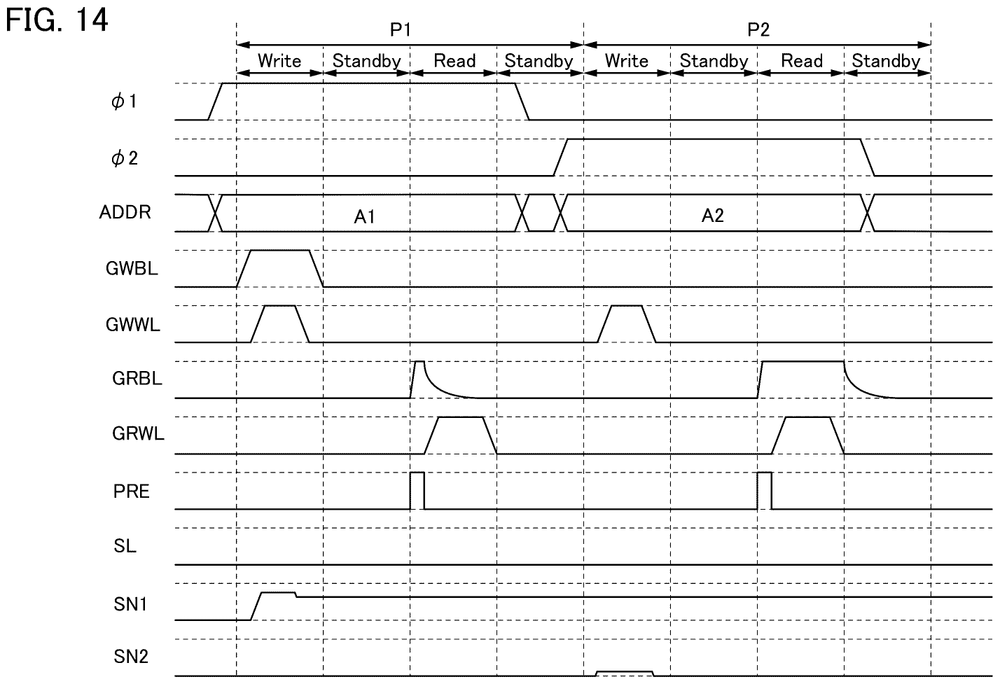

Next, an operation example of a semiconductor device that employs the configuration illustrated in FIG. 12 is described with reference to a timing chart shown in FIG. 14.

The operation example shown in FIG. 14 is described based on the write operation and read operation of the memory cell 42 described in FIG. 5C. That is, the wiring SL is set to VSS, and the read operation is performed while pre-charging the wiring RBL (corresponding to the wiring GRBL) to VDD.

The period P1 is a period during which the address A1 (ADDR) of the memory cell 42 included in the element layer 40[1] is accessed. The period P2 is a period during which the address A2 (ADDR) of the memory cell 42 included in the element layer 40[2] is accessed. In the periods P1 and P2, periods of write operation (Write), read operation (Read), and a standby state (Standby) are provided. In the period during which the element layer 40[1] is accessed, the signal φ1 is set in a selected state (an H level). In the period during which the element layer 40[2] is accessed, the signal φ2 is set in a selected state (an H level).

In FIG. 14, a node that is connected to the gate of the transistor M2 at the address A1 of the memory cell 42 included in the element layer 40[1] is denoted by the node SN1. A node that is connected to the gate of the transistor M2 at the address A2 of the memory cell 42 included in the element layer 40[2] is denoted by the node SN2. The nodes SN1 and SN2 are described on the assumption that L-level (VSS) data is written in an initial state.

In addition, in FIG. 14, signals of the wiring GWBL, the wiring GWWL, the wiring GRBL, and the wiring GRWL and the pre-charge signal PRE can be signals supplied to wirings connected to the memory cell 42 accessed in each period through the combination of the signal φ1 and the signal φ2.

For example, in the period P1, the potential of the wiring GWWL that is at an H level is a potential selectively supplied to the wiring WWL[1] connected to the memory cell 42 included in the element layer 40[1] by the signal φ1. In addition, in the period P2, the potential of the wiring GWWL that is at an H level is a potential selectively supplied to the wiring WWL[2] connected to the memory cell 42 included in the element layer 40[2] by the signal φ2.

Furthermore, in the period P1, the potential of the wiring GWBL that is at an H level is a potential selectively supplied to the wiring WBL[1] connected to the memory cell 42 included in the element layer 40[1] by the signal φ1. Moreover, in the period P2, the potential of the wiring GWBL that is at an L level is a potential selectively supplied to the wiring WBL[2] connected to the memory cell 42 included in the element layer 40[2] by the signal φ2.

Furthermore, in the period P1, the potential of the wiring GWBL that varies depending on a potential of data written to the selected memory cell 42 is a potential selectively supplied to the wiring WBL[1] connected to the memory cell 42 included in the element layer 40[1] by the signal φ1. Moreover, in the period P2, the potential of the wiring GWBL that varies depending on the potential of data written to the selected memory cell 42 is a potential selectively supplied to the wiring WBL[2] connected to the memory cell 42 included in the element layer 40[2] by the signal φ2.

Furthermore, in the period P1, the potential of the wiring GRBL that varies depending on the potential retained in the selected memory cell 42 varies depending on a variation in the potential of RBL[1] connected to the memory cell 42 included in the element layer 40[1] selectively by the signal φ1. Moreover, in the period P2, the potential of the wiring GRBL that varies depending on the potential retained in the selected memory cell 42 varies depending on a variation in the potential of RBL[2] connected to the memory cell 42 included in the element layer 40[2] selectively by the signal φ2.

For example, in the period P1, VDD supplied in accordance with control of the pre-charge signal PRE is supplied to the wiring RBL[1] connected to the memory cell 42 included in the element layer 40[1] selectively by the signal φ1. Moreover, in the period P2, VDD supplied in accordance with control of the pre-charge signal PRE is supplied to the wiring RBL[2] connected to the memory cell 42 included in the element layer 40[2] selectively by the signal φ2.

In the period P1 during which the address A1 of the memory cell 42 included in the element layer 40[1] is accessed, data “1” is written to a predetermined memory cell 42 in the write operation (Write) while setting the signal φ1 in a selected state (an H level). The wiring GWBL and the wiring GWWL are set to an H level (VDD), and the wiring WBL[1] and the wiring WWL[1] in the element layer 40 selected by the signal φ1 are set to an H level, so that the potential of the node SN1 increases. The potential of the node SN1 slightly varies by the influence of feedthrough or charge injection in accordance with falling of the wiring GWWL (a change from VDD to VSS). The increased potential of the node SN1 is retained in and after the standby state (Standby) period. In the read operation (Read), the data “1” is read from the predetermined memory cell 42. By setting the pre-charge signal PRE to an H level, the wiring RBL[1] in the element layer 40 selected by the signal φ1 is pre-charged. By setting the wiring GRWL to an H level, the wiring RWL[1] in the element layer 40 selected by the signal φ1 is set to an H level. As a result, the wiring RBL[1] is discharged, and the wiring GRBL that is connected to the wiring RBL[1] in the element layer 40 selected by the signal φ1 is also discharged. After that, it enters the standby state (Standby) period, and the potential of the node SN1 continues to be retained.

In the period P2 during which the address A2 of the memory cell 42 included in the element layer 40[2] is accessed, data “0” is written to a predetermined memory cell 42 in the write operation (Write) while setting the signal φ2 in a selected state (an H level). The wiring GWBL is set to an L level, and the wiring WBL[2] in the element layer 40 selected by the signal φ2 is set to an L level. In addition, the wiring GWWL is set to an H level (VDD), and the wiring WWL[2] in the element layer 40 selected by the signal φ2 is set to an H level. The potential of the node SN2 slightly varies by the influence of rising of the wiring GWWL (a change from VSS to VDD) and feedthrough or charge injection in accordance with falling of the wiring GWWL; however, the potential does not change before and after the write operation (Write) period. The potential of the node SN2 is retained in and after the standby state (Standby) period. In the read operation (Read), the data “0” is read from the predetermined memory cell 42. By setting the pre-charge signal PRE to an H level, the wiring RBL[2] in the element layer 40 selected by the signal φ2 is pre-charged. By setting the wiring GRWL to an H level, the wiring RWL[2] in the element layer 40 selected by the signal φ2 is set to an H level. As a result, the wiring RBL[2] remains at an H level, and the wiring GRBL that is connected to the wiring RBL[2] in the element layer 40 selected by the signal φ2 also remains at an L level. After that, it enters the standby state (Standby) period, a potential of the wiring GRWL is discharged by off-state current of a Si transistor or the like, and the potential of the node SN2 continues to be retained.

In the semiconductor device of one embodiment of the present invention, in a configuration where data is written or read to/from memory cells provided across the plurality of element layers, the switch circuits are provided between the wirings connected to the bit line driver circuits and the wirings connected to the memory cells in the element layers. With this configuration, wirings connected to memory cells in element layers where data is not written or read to/from the memory cells can be electrically separated from wirings connected to memory cells in element layers where data is written or read to/from the memory cells.

Thus, in addition to a reduction in power consumption, an increase in density, and an increase in memory capacity by using memory cells including stacked OS transistors, wiring loads of wirings functioning as signal lines can be reduced, which results in higher-speed data reading and writing and higher data reliability.

The configuration, structure, method, and the like described in this embodiment can be used in combination as appropriate with the configurations, structures, methods, and the like described in the other embodiments, an example, and the like.

### EMBODIMENT 2

In this embodiment, configuration examples that are different from the configuration examples of the semiconductor device that is one embodiment of the present invention described in Embodiment 1 will be described.

Note that in this embodiment, description of configurations similar to the configurations in Embodiment 1 will be omitted. In this embodiment, configurations of wirings provided across the element layer 40 and the element layer 50 will be described using a schematic diagram and block diagrams, and this modification example can be applied to Embodiment 1 as appropriate.

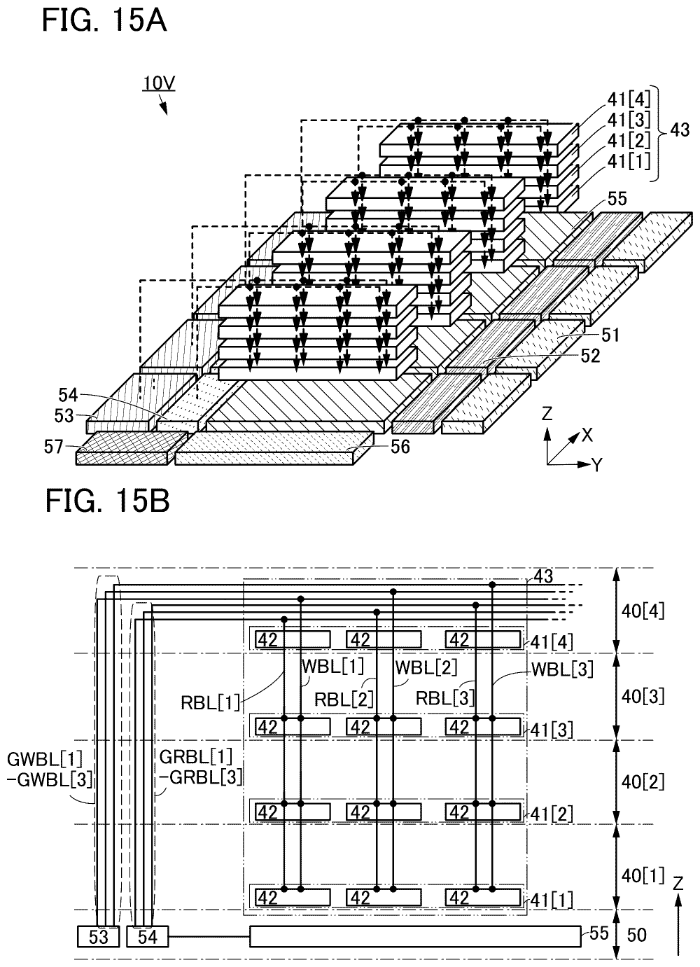

FIG. 15A and FIG. 15B are a schematic diagram and a block diagram each illustrating a configuration example of a semiconductor device according to one embodiment of the present invention. As in FIG. 1A and FIG. 1B, a semiconductor device 10V illustrated in FIG. 15A and FIG. 15B includes other element layers 40 stacked and provided over the element layer 50. For example, as illustrated in FIG. 15B, the semiconductor device 10V includes four element layers 40 (the element layers 40[1] to 40[4], which are illustrated as an example) stacked and provided over the element layer 50. In the semiconductor device 10V, data writing or reading is performed on the memory cells 42 included in the element layer 40 through a wiring from bit line driver circuits (the write bit line driver circuit 53 and the read bit line driver circuit 54) across the upper element layer 40 and a wiring from the upper element layer 40 toward the lower element layer 40, as illustrated in FIG. 15A.

In the configuration illustrated in FIG. 15A and FIG. 15B, the element layers 40 include the wirings WBL (the wirings WBL[1] to WBL[3]) for data writing of the memory cells 42 and the wirings RBL (the wirings RBL[1] to RBL[3]) for data reading. FIG. 15B illustrates, as the wirings WBL[1] to WBL[3] and the wirings RBL[1] to RBL[3], the wirings WBL and the wirings RBL that are connected to the memory cells 42 included in the element layers 40[1] to 40[4]. The wirings WBL[1] to WBL[3] and the wirings RBL[1] to RBL[3] electrically connect the memory cells 42 to the wirings GWBL or the wirings GRBL through a wiring provided in a direction perpendicular to a direction where the upper element layer 40 (the element layer 40[4] in FIG. 15B) is stacked over the element layer 50 (a direction perpendicular to the Z direction) and a wiring provided in a direction where the element layer 40 is stacked over the element layer 50 (the Z direction).

The wirings GWBL and the wirings GRBL are provided to extend from the element layer 50 to the plurality of element layers 40 in a direction where the element layers 40 are stacked over the element layer 50 (the Z direction). The wiring GWBL has a function of transmitting, to the wiring WBL of the upper element layer 40 (the element layer 40[4] in FIG. 15B), a potential corresponding to data output from the write bit line driver circuit 53. The wiring GRBL has a function of transmitting, to the read bit line driver circuit 54, a potential corresponding to data read from the memory cell 42 included in the element layer 40 to the wiring RBL of the element layer 40[4].

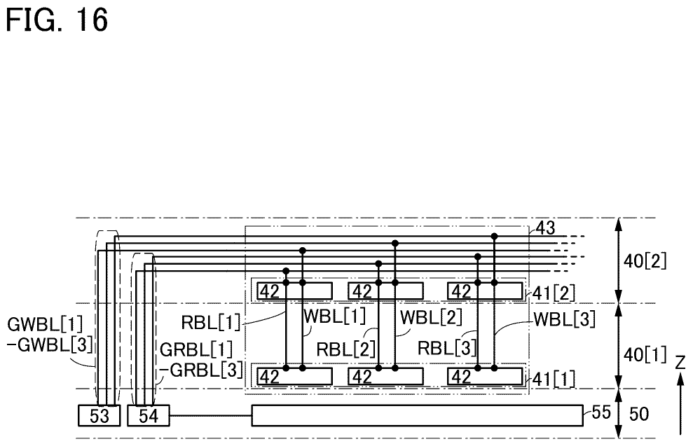

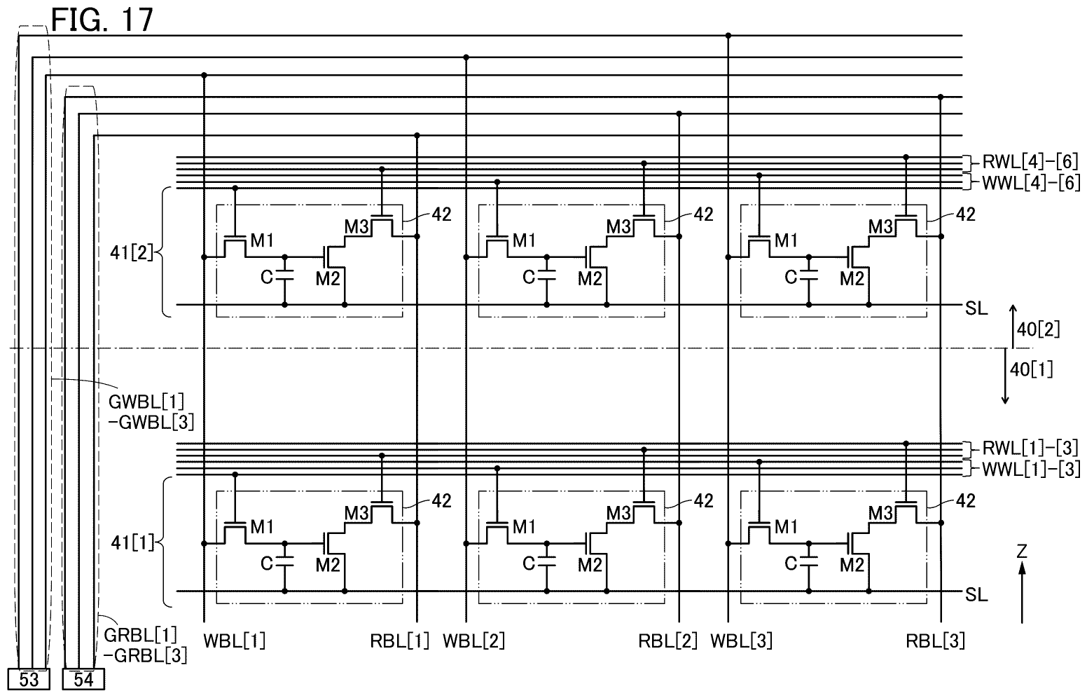

FIG. 16 illustrates the case where the element layers 40 in FIG. 15B are two layers to describe a specific example of the semiconductor device 10V. In addition, FIG. 17 is a diagram illustrating a configuration of the wirings WWL and RWL that are connected to the memory cells 42 in the element layers when the two element layers 40 illustrated in FIG. 16 are used. FIG. 17 illustrates that three memory cells 42 are provided in the memory cell portions 41[1] and 41[2]; the memory cell portions 41[1] and 41[2] are provided in the respective element layers 40. FIG. 17 illustrates the wirings WWL[1]-[6] that function as write word lines and the wirings RWL[1]-[6] that function as read word lines for controlling the memory cells 42 in the memory cell portions 41[1] and 41[2].

FIG. 17 illustrates a circuit diagram of the NOSRAM memory cells illustrated in FIG. 5A in Embodiment 1. The memory cells 42 in the memory cell portions 41[1] and 41[2] that can be placed to line up and overlap in the Z direction are connected to the common wirings WBL[1] and RBL[1] (the wirings WBL[2] and RBL[2], or the wirings WBL[3] and

RBL[3]). In addition, the three memory cells 42 included in the memory cell portion 41[1] illustrated in FIG. 17 are connected to the different wirings WWL[1]-[3] and RWL[1]-[3]. Furthermore, the three memory cells 42 included in the memory cell portion 41[2] illustrated in FIG. 17 are connected to the different wirings WWL[4]-[6] and RWL[4]-[6].

The wirings WBL and the wirings RBL include portions that are provided in a direction parallel to a direction where the wirings GWBL and the wirings GRBL are provided (the Z direction). The wirings WBL and the wirings RBL can be placed in a direction perpendicular to a plane of each of the element layers 40 by being provided in the Z direction across the plurality of element layers 40. The wiring WBL and the wiring RBL can be placed perpendicularly to other wirings provided in the element layer 40, for example, the wirings WWL and RWL. Thus, in addition to a reduction in power consumption, an increase in density, and an increase in memory capacity by using memory cells including stacked OS transistors, wiring loads of wirings functioning as signal lines can be reduced, which results in higher-speed data reading and writing and higher data reliability.

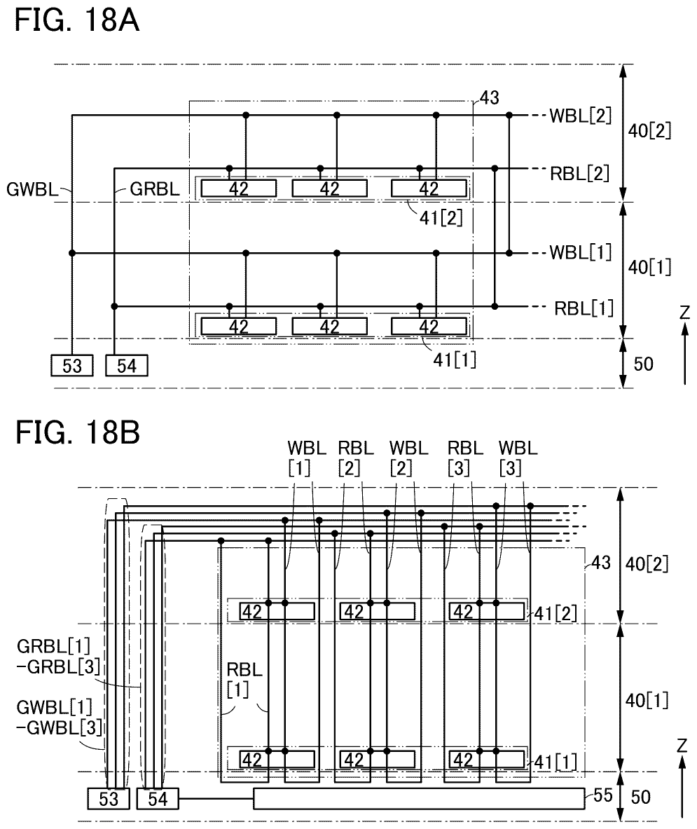

In addition, in the case where the influence of wiring resistance is larger than the influence of wiring capacitance as the wiring load, wirings for transmitting signals are preferably placed in a ring-shape (in a loop-shape). For example, FIG. 18A is a configuration example where a wiring for connecting the wiring WBL[1] and the wiring WBL[2] that are placed in different element layers 40 in the configuration of FIG. 2A described in Embodiment 1 is added in a direction parallel to the Z direction to be placed in a ring-shape (in a loop-shape). Similarly, FIG. 18A illustrates a configuration example where the wiring RBL[1] and the wiring RBL[2] that are placed in the different element layers 40 are placed in a ring-shape (in a loop-shape). Note that in FIG. 18A, a wiring for connecting the wiring WBL[1] and the wiring WBL[2] (the wiring RBL[1] and the wiring RBL[2]) is added; thus, although switch circuits are omitted, in the case where different wirings WBL (e.g., the wiring WBL[3] and the wiring WBL[4]) or different wirings RBL (e.g., the wiring RBL[3] and the wiring RBL[4]) are included, a configuration where a switch circuit is provided for each wiring WBL (each wiring RBL) placed in a ring-shape is preferable.

As another example, FIG. 18B is a configuration example where wirings for connecting the wirings WBL or the wirings RBL that are placed in different element layers 40 in the configuration of FIG. 16 described in this embodiment to the memory cells 42 are added in a direction parallel to the Z direction to be placed in a ring-shape (in a loop-shape).

Wiring resistance can be reduced when wirings for transmitting signals are placed in a ring-shape (in a loop-shape), as illustrated in FIG. 18A and FIG. 18B. Thus, wiring loads such as wiring capacitance and wiring resistance of wirings functioning as signal lines can be reduced, which results in higher-speed data reading and writing and higher data reliability.

The configuration, structure, method, and the like described in this embodiment can be used in combination as appropriate with the configurations, structures, methods, and the like described in the other embodiments, an example, and the like.

### EMBODIMENT 3

In this embodiment, configurations of transistors that can be used in the semiconductor device described in the above embodiment will be described. For example, a configuration where transistors having different electrical characteristics are stacked and provided will be described. With this configuration, the degree of freedom in design of a semiconductor device can be increased. In addition, providing transistors having different electrical characteristics to be stacked can increase the integration degree of the semiconductor device.

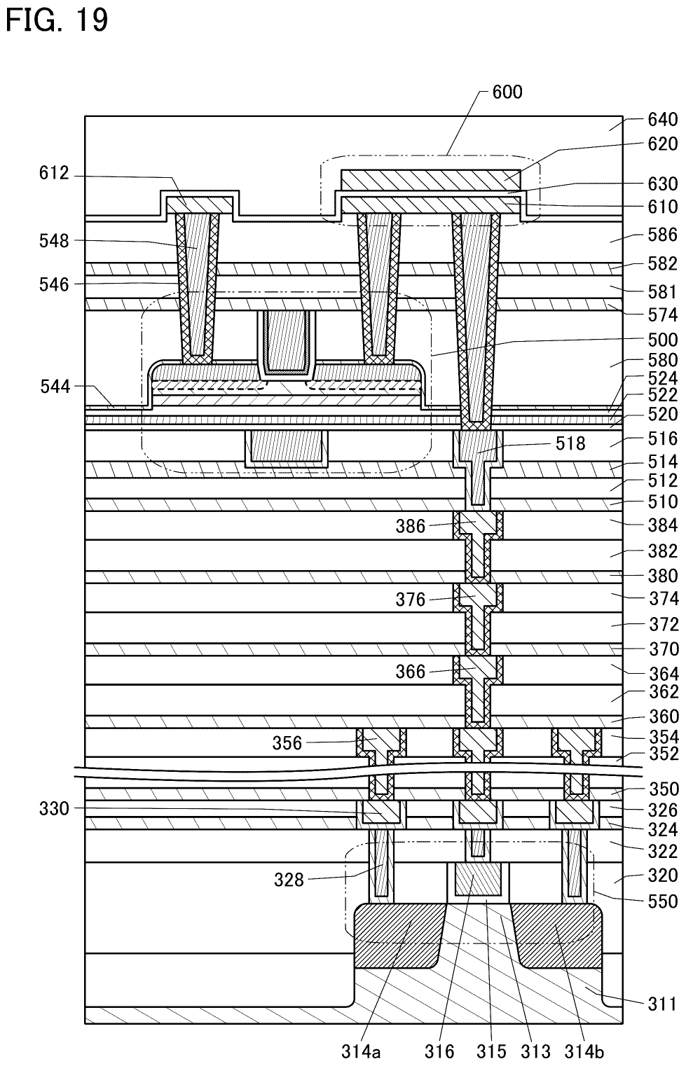

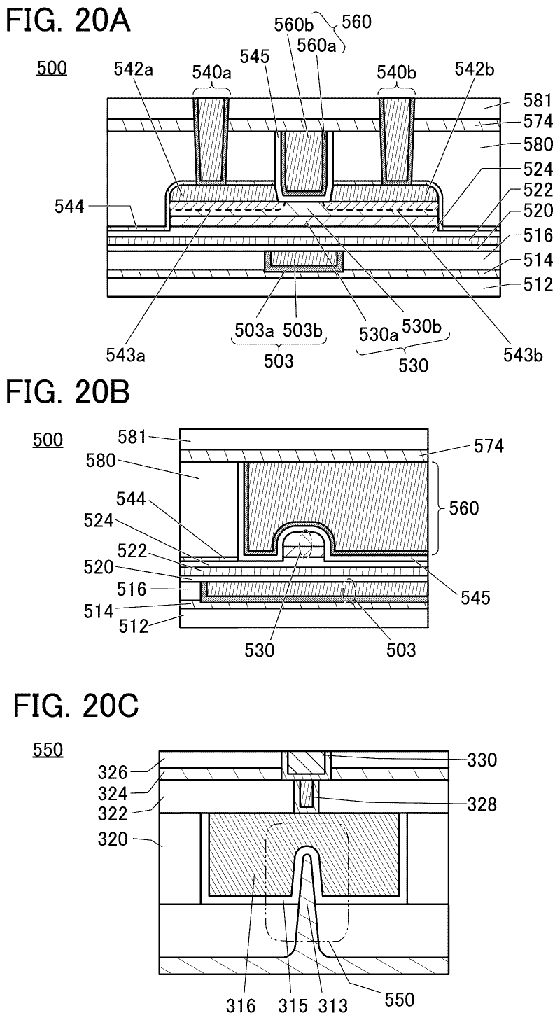

FIG. 19 illustrates part of a cross-sectional structure of a semiconductor device. The semiconductor device illustrated in FIG. 19 includes a transistor 550, a transistor 500, and a capacitor 600. FIG. 20A is a cross-sectional view of the transistor 500 in a channel length direction, FIG. 20B is a cross-sectional view of the transistor 500 in a channel width direction, and FIG. 20C is a cross-sectional view of the transistor 550 in a channel width direction. For example, the transistor 550 corresponds to the Si transistor described in the above embodiment, and the transistor 500 corresponds to an OS transistor.

In FIG. 19, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 20C, in the transistor 550, a top surface and a side surface in the channel width direction of the semiconductor region 313 are covered with the conductor 316 with the insulator 315 therebetween. The use of such a Fin-type transistor as the transistor 550 can increase the effective channel width and thus improve on-state characteristics of the transistor 550. In addition, contribution of the electric field of a gate electrode can be increased, so that the off-state characteristics of the transistor 550 can be improved. Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material including Ge (germanium), SiGe (silicon germanium), GaAs (gallium arsenide), GaAlAs (gallium aluminum arsenide), or the like. A configuration using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like. The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon including the element that imparts n-type conductivity, such as arsenic or phosphorus, or the element that imparts p-type conductivity, such as boron, or a conductive material such as a metal material, an alloy material, or a metal oxide material can be used.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance. The transistor 550 may be formed using an SOI (silicon on Insulator) substrate or the like.

In addition, as the SOI substrate, the following substrate may be used: a SIMOX (Separation by Implanted Oxygen) substrate that is formed in such a manner that after an oxygen ion is implanted into a mirror-polished wafer, an oxide layer is formed at a certain depth from a surface and defects generated in a surface layer are eliminated by high-temperature annealing, or an SOI substrate formed by using a Smart-Cut method in which a semiconductor substrate is cleaved by utilizing growth of a minute void, which is formed by implantation of a hydrogen ion, by heat treatment; an ELTRAN method (a registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, a top surface of the insulator 322 may be planarized by planarization treatment using a chemical mechanical polishing (CMP) method or the like to increase planarity.

In addition, for the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, for example, silicon nitride formed by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

In addition, a conductor 328, a conductor 330, and the like that are connected to the transistor 550 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 19, an insulator 350, an insulator 352, and an insulator 354 are sequentially stacked and provided. Furthermore, a conductor 356 is formed in the insulator 350, the insulator 352, and the insulator 354. The conductor 356 has a function of a plug connected to the transistor 550 or a wiring. Note that the conductor 356 can be provided using a material similar to those for the conductor 328 and the conductor 330.

Note that for example, as the insulator 350, like the insulator 324, an insulator having a barrier property against hydrogen is preferably used. Furthermore, the conductor 356 preferably includes a conductor having a barrier property against hydrogen. In particular, the conductor having a barrier property against hydrogen is formed in an opening portion of the insulator 350 having a barrier property against hydrogen. With this configuration, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. In addition, by stacking tantalum nitride and tungsten, which has high conductivity, diffusion of hydrogen from the transistor 550 can be inhibited while the conductivity as a wiring is kept. In that case, a configuration where a tantalum nitride layer having a barrier property against hydrogen is in contact with the insulator 350 having a barrier property against hydrogen is preferable.

A wiring layer may be provided over the insulator 354 and the conductor 356. For example, in FIG. 19, an insulator 360, an insulator 362, and an insulator 364 are sequentially stacked and provided. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, like the insulator 324, an insulator having a barrier property against hydrogen is preferably used. Furthermore, the conductor 366 preferably includes a conductor having a barrier property against hydrogen. In particular, the conductor having a barrier property against hydrogen is formed in an opening portion of the insulator 360 having a barrier property against hydrogen. With this configuration, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, in FIG. 19, an insulator 370, an insulator 372, and an insulator 374 are sequentially stacked and provided. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, like the insulator 324, an insulator having a barrier property against hydrogen is preferably used. Furthermore, the conductor 376 preferably includes a conductor having a barrier property against hydrogen. In particular, the conductor having a barrier property against hydrogen is formed in an opening portion of the insulator 370 having a barrier property against hydrogen. With this configuration, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, in FIG. 19, an insulator 380, an insulator 382, and an insulator 384 are sequentially stacked and provided. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, like the insulator 324, an insulator having a barrier property against hydrogen is preferably used. Furthermore, the conductor 386 preferably includes a conductor having a barrier property against hydrogen. In particular, the conductor having a barrier property against hydrogen is formed in an opening portion of the insulator 380 having a barrier property against hydrogen. With this configuration, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device according to this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Therefore, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

In addition, for the film having a barrier property against hydrogen, a metal oxide such as aluminum oxide, hafnium oxide, or tantalum oxide is preferably used for each of the insulator 510 and the insulator 514, for example.

In particular, aluminum oxide has an excellent blocking effect that prevents passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after a manufacturing process of the transistor. In addition, release of oxygen from the oxide included in the transistor 500 can be inhibited. Therefore, aluminum oxide is suitably used for a protective film of the transistor 500.

In addition, for each of the insulator 512 and the insulator 516, a material similar to that for the insulator 320 can be used, for example. Furthermore, when a material with comparatively low permittivity is used for these insulators, parasitic capacitance generated between wirings can be reduced. A silicon oxide film, a silicon oxynitride film, or the like can be used for each of the insulator 512 and the insulator 516, for example.

Furthermore, a conductor 518, a conductor included in the transistor 500 (a conductor 503, for example), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this configuration, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided above the insulator 516.

As illustrated in FIG. 20A and FIG. 20B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; a metal oxide 530a positioned over the insulator 524; a metal oxide 530b positioned over the metal oxide 530a; a conductor 542a and a conductor 542b positioned apart from each other over the metal oxide 530b; an insulator 580 that is positioned over the conductor 542a and the conductor 542b and is provided with an opening formed to overlap a region between the conductor 542a and the conductor 542b; an insulator 545 positioned on a bottom surface and a side surface of the opening; and a conductor 560 positioned on a formation surface of the insulator 545.

In addition, as illustrated in FIG. 20A and FIG. 20B, an insulator 544 is preferably positioned between the insulator 580 and the metal oxide 530a, the metal oxide 530b, the conductor 542a, and the conductor 542b. Furthermore, as illustrated in FIG. 20A and FIG. 20B, the conductor 560 preferably includes a conductor 560a provided inside the insulator 545 and a conductor 560b provided to be embedded inside the conductor 560a. Moreover, as illustrated in FIG. 20A and FIG. 20B, an insulator 574 is preferably positioned over the insulator 580, the conductor 560, and the insulator 545.

Note that in this specification and the like, the metal oxide 530a and the metal oxide 530b are sometimes collectively referred to as a metal oxide 530.

Note that the transistor 500 is illustrated to have a configuration where two layers, the metal oxide 530a and the metal oxide 530b, are stacked in the region where the channel is formed and its vicinity; however, the present invention is not limited thereto. For example, a single layer of the metal oxide 530b or a stacked-layer configuration of three or more layers may be provided.

In addition, although the conductor 560 has a stacked-layer configuration of two layers in the transistor 500, the present invention is not limited thereto. For example, the conductor 560 may have a single-layer configuration or a stacked-layer configuration of three or more layers. Furthermore, the transistor 500 illustrated in FIG. 19 and FIG. 20A is an example and the configuration is not limited thereto; an appropriate transistor is used in accordance with a circuit configuration, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and higher integration of the semiconductor device can be achieved.

In addition, since the conductor 560 is formed in the region between the conductor 542a and the conductor 542b in a self-aligned manner, the conductor 560 does not have a region overlapping the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to overlap the metal oxide 530 and the conductor 560. Thus, when a potential is applied to the conductor 560 and the conductor 503, an electric field generated from the conductor 560 and an electric field generated from the conductor 503 are connected, so that the channel formation region formed in the metal oxide 530 can be covered.

In this specification and the like, a transistor structure where a channel formation region is electrically surrounded by an electric field of a first gate electrode is referred to as a surrounded channel (S-channel) structure. In addition, the S-channel structure disclosed in this specification and the like has a structure different from a Fin-type structure and a planar structure. Meanwhile, the S-channel structure disclosed in this specification and the like can also be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor has the S-channel structure, the channel formation region can be electrically surrounded. Note that since the S-channel structure is a structure where the channel formation region is electrically surrounded, it can also be said that the S-channel structure is a structure substantially equivalent to a GAA (Gate All Around) structure or an LGAA (Lateral Gate All Around) structure. When the transistor has the S-channel structure, the GAA structure, or the LGAA structure, a channel formation region that is formed at an interface between the metal oxide 530 and a gate insulator or in the vicinity of the interface can be the entire bulk of the metal oxide 530. Accordingly, the density of current flowing through the transistor can be improved, which can be expected to improve the on-state current of the transistor or increase the field-effect mobility of the transistor.

In addition, the conductor 503 has a configuration similar to that of the conductor 518; a conductor 503a is formed in contact with an inner wall of an opening in the insulator 514 and the insulator 516, and a conductor 503b is formed on the inner side. Note that although the conductor 503a and the conductor 503b are stacked in the transistor 500, the present invention is not limited thereto. For example, the conductor 503 may be provided as a single layer or to have a stacked-layer configuration of three or more layers.

Here, for the conductor 503a, a conductive material that has a function of inhibiting diffusion of impurities such as a hydrogen atom, a hydrogen molecule, a water molecule, and a copper atom (through which the impurities do not easily pass) is preferably used.

Alternatively, it is preferable to use a conductive material that has a function of inhibiting diffusion of oxygen (e.g., at least one of an oxygen atom, an oxygen molecule, and the like) (through which oxygen does not easily pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that includes tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer configuration.

The insulator 520, the insulator 522, and the insulator 524 have a function of a second gate insulating film.

Here, an insulator including oxygen more than that in the stoichiometric composition is preferably used as the insulator 524 in contact with the metal oxide 530. Such oxygen is easily released from the insulator by heating. In this specification and the like, oxygen released by heating is sometimes referred to as “excess oxygen.” That is, a region including excess oxygen (also referred to as an “excess-oxygen region”) is preferably formed in the insulator 524. When such an insulator including excess oxygen is provided in contact with the metal oxide 530, oxygen vacancies (Vo) in the metal oxide 530 can be reduced and the reliability of the transistor 500 can be improved. Note that when hydrogen enters the oxygen vacancies in the metal oxide 530, such defects (hereinafter, referred to as VoH in some cases) serve as donors and generate electrons serving as carriers in some cases. In addition, in some cases, bonding of part of hydrogen to oxygen bonded to a metal atom generates electrons serving as carriers. Thus, a transistor using an oxide semiconductor that includes a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen. In one embodiment of the present invention, VoH in the metal oxide 530 is preferably reduced as much as possible so that the metal oxide 530 becomes a highly purified intrinsic or substantially highly purified intrinsic oxide. It is important to remove impurities such as moisture and hydrogen in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose VoH is sufficiently reduced. When an oxide semiconductor with sufficiently reduced impurities such as VoH is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of higher than or equal to 100° C. and lower than or equal to 700° C., or higher than or equal to 100° C. and lower than or equal to 400° C.

In addition, any one or more of heat treatment, microwave treatment, and RF treatment may be performed in a state in which the insulator including the excess-oxygen region and the metal oxide 530 are in contact with each other. By the treatment, water or hydrogen in the metal oxide 530 can be removed. For example, in the metal oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the metal oxide 530 or an insulator in the vicinity of the metal oxide 530 in some cases. In other cases, part of hydrogen is gettered by the conductors 542a and 542b.

In addition, for the microwave treatment, for example, it is suitable to use an apparatus including a power supply that generates high-density plasma or an apparatus including a power supply that applies RF to a substrate side. For example, high-density oxygen radicals can be generated with the use of an oxygen-containing gas and high-density plasma, and by applying RF to the substrate side, the oxygen radicals generated by the high-density plasma can be efficiently introduced into the metal oxide 530 or the insulator in the vicinity of the metal oxide 530. Furthermore, pressure in the microwave treatment is higher than or equal to 133 Pa, preferably higher than or equal to 200 Pa, further preferably higher than or equal to 400 Pa. Moreover, as a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In addition, in the manufacturing process of the transistor 500, it is suitable to perform the heat treatment with the surface of the metal oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the metal oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then heat treatment is performed in an atmosphere including an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere including an oxidizing gas at higher than or equal to 10 ppm, higher than or equal to 1%, or higher than or equal to 10%, and then heat treatment is successively performed in a nitrogen gas or inert gas atmosphere.

Note that oxygen adding treatment performed on the metal oxide 530 can promote reaction in which oxygen vacancies in the metal oxide 530 are filled with supplied oxygen, i.e., reaction of “Vo+O→null.” Furthermore, hydrogen remaining in the metal oxide 530 reacts with supplied oxygen, so that the hydrogen can be removed as H₂O (dehydration). This can inhibit recombination of hydrogen remaining in the metal oxide 530 with oxygen vacancies and formation of VoH.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen does not easily pass).

When the insulator 522 has a function of inhibiting diffusion of oxygen, impurities, or the like, oxygen included in the metal oxide 530 is not diffused into the insulator 520 side, which is preferable. Furthermore, the conductor 503 can be inhibited from reacting with oxygen included in the insulator 524, the metal oxide 530, or the like.

For the insulator 522, a single layer or stacked layers of an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and higher integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (through which oxygen does not easily pass). Aluminum oxide, hafnium oxide, an oxide including aluminum and hafnium (hafnium aluminate), or the like is preferably used for the insulator including an oxide of one or both of aluminum and hafnium. In the case where the insulator 522 is formed using such a material, the insulator 522 functions as a layer that inhibits release of oxygen from the metal oxide 530 or mixing of impurities such as hydrogen from the periphery of the transistor 500 into the metal oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. A stack of the insulator and silicon oxide, silicon oxynitride, or silicon nitride may be used.

In addition, it is preferable that the insulator 520 be thermally stable. For example, silicon oxide and silicon oxynitride are suitable because they are thermally stable.

Furthermore, the combination of an insulator that is a high-k material and silicon oxide or silicon oxynitride enables the insulator 520 to have a stacked-layer configuration that has thermal stability and high relative permittivity.

Note that in the transistor 500 in FIG. 20A and FIG. 20B, the insulator 520, the insulator 522, and the insulator 524 are illustrated as the second gate insulating film having a stacked-layer configuration of three layers; however, the second gate insulating film may be a single layer or may have a stacked-layer configuration of two layers or four or more layers. In that case, without limitation to a stacked-layer configuration formed of the same material, a stacked-layer configuration formed of different materials may be employed.

In the transistor 500, a metal oxide functioning as an oxide semiconductor is used as the metal oxide 530 including the channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

In addition, as the metal oxide functioning as the channel formation region in the metal oxide 530, a metal oxide whose bandgap is wider than or equal to 2 eV, preferably wider than or equal to 2.5 eV is preferably used. The use of a metal oxide having such a wide bandgap can reduce the off-state current of the transistor.

When the metal oxide 530 includes the metal oxide 530a under the metal oxide 530b, it is possible to inhibit diffusion of impurities into the metal oxide 530b from the components formed below the metal oxide 530a.

Note that the metal oxide 530 preferably has a plurality of oxide layers that differ in the atomic ratio of metal atoms. Specifically, the atomic ratio of the element M to the constituent elements in the metal oxide used as the metal oxide 530a is preferably higher than the atomic ratio of the element M to the constituent elements in the metal oxide used as the metal oxide 530b. In addition, the atomic ratio of the element M to In in the metal oxide used as the metal oxide 530a is preferably higher than the atomic ratio of the element M to In in the metal oxide used as the metal oxide 530b. Furthermore, the atomic ratio of In to the element M in the metal oxide used as the metal oxide 530b is preferably higher than the atomic ratio of In to the element M in the metal oxide used as the metal oxide 530a.

In addition, the energy of the conduction band minimum of the metal oxide 530a is preferably higher than the energy of the conduction band minimum of the metal oxide 530b. In other words, the electron affinity of the metal oxide 530a is preferably smaller than the electron affinity of the metal oxide 530b.

Here, the energy level of the conduction band minimum gradually changes at a junction portion of the metal oxide 530a and the metal oxide 530b. In other words, the energy level of the conduction band minimum at the junction portion of the metal oxide 530a and the metal oxide 530b continuously changes or is continuously connected. To change the energy level gradually, the density of defect states in a mixed layer formed at an interface between the metal oxide 530a and the metal oxide 530b is preferably made low.

Specifically, when the metal oxide 530a and the metal oxide 530b include a common element (as a main component) in addition to oxygen, a mixed layer with a low density of defect states can be formed. For example, in the case where the metal oxide 530b is an In—Ga—Zn oxide, an In—Ga—Zn oxide, a Ga—Zn oxide, gallium oxide, or the like is preferably used for the metal oxide 530a.

At this time, the metal oxide 530b serves as a main carrier path. When the metal oxide 530a has the above configuration, the density of defect states at the interface between the metal oxide 530a and the metal oxide 530b can be made low. Thus, the influence of interface scattering on carrier conduction is small, and the transistor 500 can have high on-state current.

Note that although this embodiment illustrates an example of the metal oxide 530 having a two-layer structure of the metal oxide 530a and the metal oxide 530b over the metal oxide 530a, the metal oxide 530 is not limited thereto. For example, the metal oxide 530 may have a three-layer structure of the metal oxide 530a, the metal oxide 530b, and a metal oxide 530c (not illustrated) that are formed in this order. When the metal oxide 530c has a composition equivalent to that of the metal oxide 530a, it is possible to inhibit diffusion of impurities into the metal oxide 530b from the components formed above the metal oxide 530c. In addition, when a structure where the metal oxide 530b is sandwiched between the metal oxide 530a and the metal oxide 530c (what is called an embedded channel structure) is employed, the channel formation region can be kept away from an insulating film interface. Note that when the embedded channel structure is employed, carrier interface scattering can be reduced, and a transistor that has high field-effect mobility can be achieved.

The conductor 542a and the conductor 542b functioning as the source electrode and the drain electrode are provided over the metal oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including the above metal element; an alloy including a combination of the above metal elements; or the like. For example, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. In addition, tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer configuration are illustrated in FIG. 20A, a stacked-layer configuration of two or more layers may be employed. For example, it is preferable to stack a tantalum nitride film and a tungsten film. Alternatively, a titanium film and an aluminum film may be stacked.

Alternatively, a two-layer configuration where an aluminum film is stacked over a tungsten film, a two-layer configuration where a copper film is stacked over a copper-magnesium-aluminum alloy film, a two-layer configuration where a copper film is stacked over a titanium film, or a two-layer configuration where a copper film is stacked over a tungsten film may be employed.

Other examples include a three-layer configuration where a titanium film or a titanium nitride film is formed, an aluminum film or a copper film is stacked over the titanium film or the titanium nitride film, and a titanium film or a titanium nitride film is formed over the aluminum film or the copper film; and a three-layer configuration where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

In addition, as illustrated in FIG. 20A, a region 543a and a region 543b are sometimes formed as low-resistance regions at an interface between the metal oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the metal oxide 530, the oxygen concentration in the region 543a (the region 543b) sometimes decreases. In addition, a metal compound layer that includes the metal included in the conductor 542a (the conductor 542b) and the component of the metal oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. In that case, the insulator 544 may be provided to cover a side surface of the metal oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator including an oxide of one or both of aluminum and hafnium, such as aluminum oxide, hafnium oxide, or an oxide including aluminum and hafnium (hafnium aluminate), as the insulator 544. In particular, hafnium aluminate has higher heat resistance than a hafnium oxide film. Therefore, hafnium aluminate is preferable because it is not easily crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

When the insulator 544 is included, diffusion of impurities such as water and hydrogen included in the insulator 580 into the metal oxide 530b can be inhibited. Furthermore, oxidation of the conductors 542a and 542b due to excess oxygen included in the insulator 580 can be inhibited.

The insulator 545 functions as a first gate insulating film. Like the insulator 524, the insulator 545 is preferably formed using an insulator that includes excess oxygen and releases oxygen by heating.

Specifically, silicon oxide including excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator including excess oxygen is provided as the insulator 545, oxygen can be effectively supplied from the insulator 545 to the channel formation region of the metal oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the metal oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the metal oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer configuration like the second gate insulating film. As miniaturization and high integration of transistors progress, a problem such as off-state current might arise because of a thinner gate insulating film. For that reason, when the insulator functioning as the gate insulating film has a stacked-layer configuration of a high-k material and a thermally stable material, a gate potential during transistor operation can be reduced while the physical thickness is maintained. Furthermore, the stacked-layer configuration can be thermally stable and have high relative permittivity.

Although the conductor 560 that functions as the first gate electrode and has a two-layer configuration is illustrated in FIG. 20A and FIG. 20B, a single-layer configuration or a stacked-layer configuration of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen included in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be used as the metal oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material including tungsten, copper, or aluminum as its main component is preferably used for the conductor 560b. Furthermore, the conductor 560b also functions as a wiring and thus a conductor having high conductivity is preferably used. For example, a conductive material including tungsten, copper, or aluminum as its main component can be used. Moreover, the conductor 560b may have a stacked-layer configuration, for example, a stacked-layer configuration of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the metal oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited by a sputtering method, excess-oxygen regions can be provided in the insulator 545 and the insulator 580. Accordingly, oxygen can be supplied from the excess-oxygen regions to the metal oxide 530.

For example, a metal oxide including one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The configurations of the conductor 540a and the conductor 540b are similar to those of a conductor 546 and a conductor 548 that will be described later.

An insulator 582 is provided over the insulator 581. A substance having a barrier property against oxygen, hydrogen, or the like is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with comparatively low permittivity is used for these insulators, parasitic capacitance between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

In addition, after the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. Note that when an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the manufacturing steps of the transistor 500. Note that the insulator having a high barrier property against hydrogen or water is formed using a material similar to that for the insulator 522 or the insulator 514, for example.

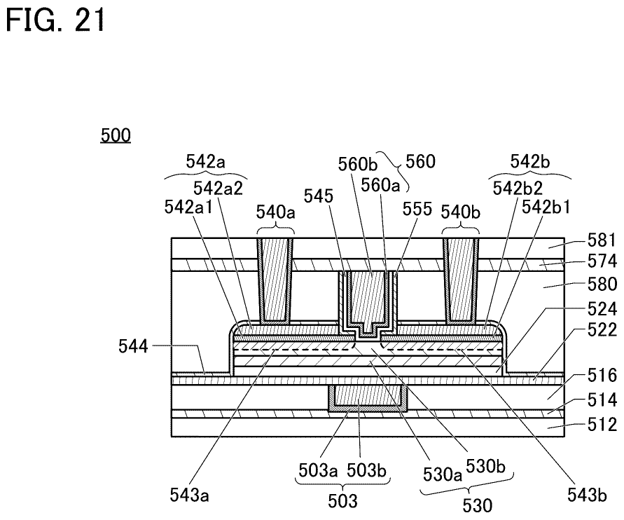

Note that the transistors that can be used in the present invention are not limited to the transistor 500 illustrated in FIG. 20A and FIG. 20B. For example, the transistor 500 having a structure illustrated in FIG. 21 may be used. The transistor 500 illustrated in FIG. 21 differs from the transistor illustrated in FIG. 20A and FIG. 20B in that an insulator 555 is used and that the conductor 542a and the conductor 542b have a stacked-layer structure of a conductor 542a1 and a conductor 542a2 and a stacked-layer structure of a conductor 542b1 and a conductor 542b2, respectively.

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 that are in contact with the metal oxide 530b are preferably conductors that are not easily oxidized, such as metal nitride. This can prevent excessive oxidation of the conductor 542a and the conductor 542b by oxygen included in the metal oxide 530b. In addition, the conductor 542a2 and the conductor 542b2 are preferably conductors that have higher conductivity than the conductor 542a1 and the conductor 542b1, such as metal layers. This allows the conductor 542a and the conductor 542b to function as wirings or electrodes having high conductivity. In this manner, it is possible to provide a semiconductor device where the conductor 542a and the conductor 542b that function as wirings or electrodes are provided in contact with a top surface of the metal oxide 530 that functions as an active layer.

A metal nitride is preferably used for the conductors 542a1 and 542b1. For example, a nitride including tantalum, a nitride including titanium, a nitride including molybdenum, a nitride including tungsten, a nitride including tantalum and aluminum, a nitride including titanium and aluminum, or the like is preferably used. In one embodiment of the present invention, a nitride including tantalum is particularly preferable. Alternatively, for example, ruthenium, ruthenium oxide, ruthenium nitride, an oxide including strontium and ruthenium, an oxide including lanthanum and nickel, or the like may be used. These materials are preferable because they are conductive materials that are not easily oxidized or materials that keep their conductivity even when absorbing oxygen.

In addition, the conductor 542a2 and the conductor 542b2 preferably have higher conductivity than the conductor 542a1 and the conductor 542b1. For example, film thickness of the conductor 542a2 and the conductor 542b2 is preferably larger than film thickness of the conductor 542a1 and the conductor 542b1. As each of the conductor 542a2 and the conductor 542b2, a conductor that can be used as the conductor 560b is used. With such a structure, resistance of the conductor 542a2 and the conductor 542b2 can be reduced.

For example, tantalum nitride or titanium nitride can be used for the conductor 542a1 and the conductor 542b1, and tungsten can be used for the conductor 542a2 and the conductor 542b2.

As illustrated in FIG. 21, in a cross-sectional view in the channel length direction of the transistor 500, the distance between the conductor 542a1 and the conductor 542b1 is shorter than the distance between the conductor 542a2 and the conductor 542b2. With such a configuration, the distance between a source and a drain can be further shortened, which can shorten channel length. Thus, the frequency characteristics of the transistor 500 can be improved. Through miniaturization of the semiconductor device in this manner, a semiconductor device with higher operating speed can be provided.

The insulator 555 is preferably an insulator that is not easily oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is preferably an inorganic insulator that is not easily oxidized because it is exposed to an oxidizing atmosphere. In addition, the insulator 555 is preferably an inorganic insulator that does not easily oxidize the conductors 542a2 and 542b2 because it is in contact with the conductor 542a2 and the conductor 542b2. Thus, an insulating material having a barrier property against oxygen is preferably used for the insulator 555. For example, silicon nitride can be used for the insulator 555.

The transistor 500 illustrated in FIG. 21 is formed by formation of an opening in the insulator 580 and the insulator 544, formation of the insulator 555 in contact with sidewalls of the opening, and division of the conductor 542a1 and the conductor 542b1 with the use of a mask. Here, the opening overlaps a region between the conductor 542a2 and the conductor 542b2. In addition, parts of the conductor 542a1 and the conductor 542b1 are formed to protrude inside the opening. Thus, the insulator 555 is in contact with, in the opening, a top surface of the conductor 542a1, a top surface of the conductor 542b1, a side surface of the conductor 542a2, and a side surface of the conductor 542b2. Furthermore, the insulator 545 is in contact with a top surface of the metal oxide 530 in a region between the conductor 542a1 and the conductor 542b1.

After the conductor 542a1 and the conductor 542b1 are divided, heat treatment is preferably performed in an oxygen-containing atmosphere before deposition of the insulator 545. Accordingly, oxygen can be supplied to the metal oxide 530a and the metal oxide 530b so that oxygen vacancies can be reduced. In addition, when the insulator 555 is formed in contact with the side surface of the conductor 542a2 and the side surface of the conductor 542b2, the conductor 542a2 and the conductor 542b2 can be prevented from being excessively oxidized. Consequently, electrical characteristics and reliability of the transistor can be improved. Furthermore, variation in electrical characteristics of a plurality of transistors formed over the same substrate can be suppressed.

In addition, in the transistor 500, as illustrated in FIG. 21, the insulator 524 may be formed into an island shape. Here, the insulator 524 may be formed to have a side edge that is substantially aligned with a side edge of the metal oxide 530.

In addition, in the transistor 500, as illustrated in FIG. 21, a configuration may be employed in which the insulator 522 is in contact with the insulator 516 and the conductor 503.

In other words, a configuration may be employed in which the insulator 520 illustrated in FIG. 20A and FIG. 20B is not provided.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film including an element selected from molybdenum, titanium, tantalum, tungsten, aluminum, copper, chromium, neodymium, and scandium; a metal nitride film including the above element as its component (a tantalum nitride film, a titanium nitride film, a molybdenum nitride film, or a tungsten nitride film); or the like can be used. Alternatively, it is possible to employ a conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

Although the conductor 612 and the conductor 610 each having a single-layer configuration are illustrated in this embodiment, the configuration is not limited thereto; a stacked-layer configuration of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed at the same time as another component such as a conductor, copper (Cu), aluminum (Al), or the like, which is a low-resistance metal material, may be used.

An insulator 640 is provided over the conductor 620 and the insulator 630. The insulator 640 can be provided using a material similar to that for the insulator 320. In addition, the insulator 640 may function as a planarization film that covers an uneven shape therebelow.

With the use of this configuration, a semiconductor device using a transistor including an oxide semiconductor can be miniaturized or highly integrated.

As a substrate that can be used for the semiconductor device according to one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be used. Alternatively, a plastic substrate having heat resistance to processing temperature in this embodiment may be used. Examples of the glass substrate include barium borosilicate glass, aluminosilicate glass, aluminoborosilicate glass, and soda lime glass. Alternatively, crystallized glass or the like can be used.

Alternatively, a flexible substrate; an attachment film; paper or a base film including a fibrous material; or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic evaporated film, and paper. In particular, the use of a semiconductor substrate, a single crystal substrate, an SOI substrate, or the like for the manufacture of transistors enables the manufacture of small-sized transistors with a small variation in characteristics, size, shape, or the like and high current capability. When a circuit is formed with such transistors, lower power consumption of the circuit or higher integration of the circuit can be achieved.

Alternatively, a flexible substrate may be used as the substrate, and a transistor, a resistor, a capacitor, and/or the like may be formed directly on the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. Note that as the separation layer, a stacked-layer configuration of a tungsten film and a silicon oxide film that are inorganic films, a configuration where an organic resin film of polyimide or the like is formed over a substrate, a silicon film including hydrogen, or the like can be used, for example.

That is, a semiconductor device may be formed over one substrate and then transferred to another substrate. Examples of a substrate to which a semiconductor device is transferred include, in addition to the above substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of these substrates, the manufacture of a flexible semiconductor device, the manufacture of a robust semiconductor device, provision of high heat resistance, a reduction in weight, or a reduction in thickness can be achieved.

Providing a semiconductor device over a flexible substrate can inhibit an increase in weight and can provide a robust semiconductor device.

Note that the transistor 550 illustrated in FIG. 19 is an example and the configuration is not limited thereto; an appropriate transistor is used in accordance with a circuit configuration, a driving method, or the like. For example, when the semiconductor device is a circuit having single polarity that is composed of only OS transistors, which means a circuit formed using the same-polarity transistors such as n-channel transistors only, for example, the transistor 550 has a configuration similar to that of the transistor 500.

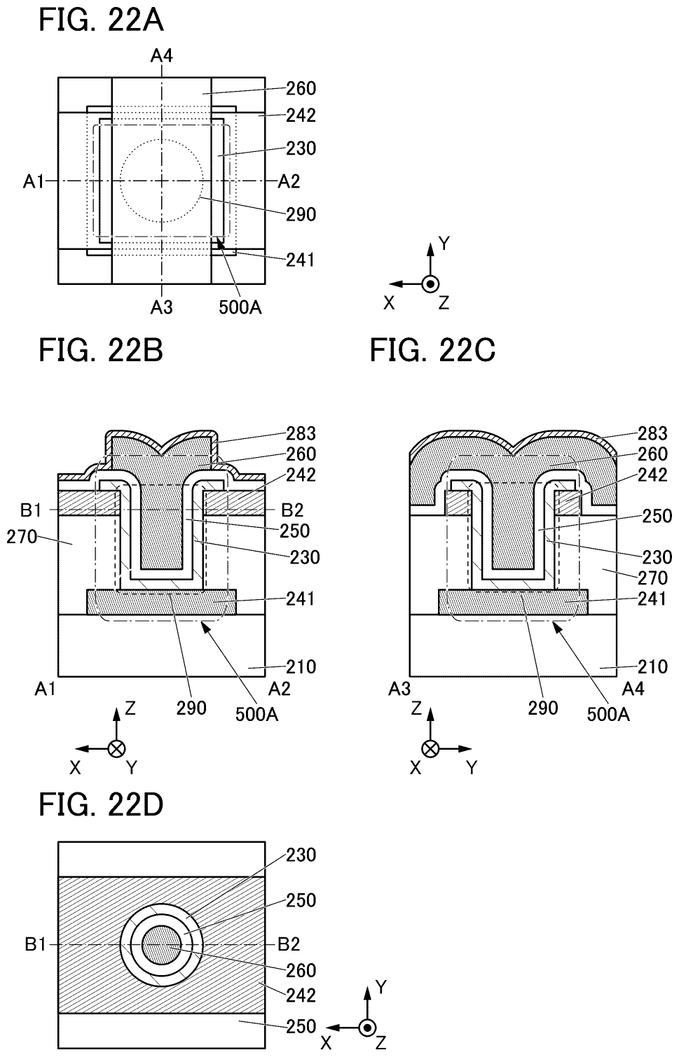

Note that the transistors that can be used in the present invention are not limited to the transistors 500 illustrated in FIG. 20A, FIG. 20B, and FIG. 21. For example, a transistor 500A having structures illustrated in FIG. 22A to FIG. 22D may be used. The transistor 500A illustrated in FIG. 22A to FIG. 22D differs from the transistors illustrated in FIG. 20A, FIG. 20B, and FIG. 21 in that the transistor 500A is a vertical channel type transistor.

FIG. 22A to FIG. 22D are top views and cross-sectional views each illustrating a transistor configuration example. FIG. 22A is a top view of the transistor 500A. FIG. 22B is a cross-sectional view of a portion indicated by a dashed-dotted line A1-A2 in FIG. 22A, and FIG. 22C is a cross-sectional view of a portion indicated by a dashed-dotted line A3-A4 in FIG. 22A. FIG. 22D is a top view of a portion indicated by a dashed-dotted line B1-B2 in FIG. 22B. Note that in the top views of FIG. 22A and FIG. 22D, some components are omitted for clarity of the drawings.

The transistor 500A includes a conductor 241 and an insulator 270 over an insulator 210, a metal oxide 230 over the conductor 241, an insulator 250 over the metal oxide 230, a conductor 260 over the insulator 250, and a conductor 242 over the insulator 270.

The conductor 241 includes a region that functions as one of a source electrode and a drain electrode of the transistor 500A. The conductor 242 includes a region that functions as the other of the source electrode and the drain electrode of the transistor 500A. The conductor 260 includes a region that functions as a gate electrode of the transistor 500A. The metal oxide 230 includes a region that functions as a channel formation region.

For the metal oxide 230, each of the materials described as the metal oxide 530a and the metal oxide 530b can be used.

The metal oxide 230 includes the channel formation region, and a source region and a drain region that are provided to sandwich the channel formation region in the transistor 500A. At least part of the channel formation region overlaps the conductor 260. The source region overlaps one of the conductor 241 and the conductor 242, and the drain region overlaps the other of the conductor 241 and the conductor 242.

An opening portion 290 that reaches the conductor 241 is provided in the conductor 242 and the insulator 270. In addition, the opening portion 290 includes a region that overlaps the conductor 241 in the top view. Furthermore, at least parts of the metal oxide 230, the insulator 250, and the conductor 260 are placed in the opening portion 290. Note that it can be said that the opening portion 290 includes an opening portion included in the conductor 242 and an opening included in the insulator 270. Moreover, it can be said that the conductor 242 includes an opening that overlaps the conductor 241 in the top view.

The metal oxide 230 is provided in contact with side surfaces and bottom surfaces of the conductor 242 and the opening portion 290 provided in the insulator 270. In other words, the metal oxide 230 includes regions that are in contact with the side surfaces of the conductor 242 and the opening portion 290 provided in the insulator 270, and top surfaces of the conductors 241 and 242. In addition, the metal oxide 230 includes a depressed portion. The depressed portion includes a region that overlaps the opening portion 290 included in the conductor 242 in the top view.

At least part of the insulator 250 is provided in the depressed portion of the metal oxide 230. In addition, the insulator 250 includes a region that is in contact with a top surface of the metal oxide 230. Furthermore, the insulator 250 includes a depressed portion. The depressed portion is positioned inside the depressed portion of the metal oxide 230.

The conductor 260 is provided to fill the depressed portion of the insulator 250. In addition, the conductor 260 includes a region that is in contact with a top surface of the insulator 250. Furthermore, the conductor 260 includes a region that overlaps the metal oxide 230 with the insulator 250 therebetween in a region between the conductor 241 and the conductor 242 in the cross-sectional view. Note that the conductor 260 whose bottom shape is a needle-like shape may be referred to as a needle-like gate.

In the above configuration, channel length of the transistor 500A is the distance from the top surface of the conductor 241 to the bottom surface of the conductor 242 in the cross-sectional view. That is, the channel length of the transistor 500A can be adjusted by film thickness of the insulator 270 in the region that overlaps the conductor 241. For example, a reduction in the film thickness of the insulator 270 enables manufacture of the transistor 500A with shorter channel length.

In addition, in the above configuration, channel width of the transistor 500A is length of a region where the insulator 270 and the metal oxide 230 are in contact with each other in the top view and is also length of the outline (outer circumference) of the metal oxide 230 in the top view. That is, the channel width of the transistor 500A can be adjusted by the diameter of an opening provided in the insulator 270. For example, an increase in the diameter of the opening enables manufacture of the transistor 500A with larger channel width. Note that the opening can be rephrased as an opening provided with some components of the transistor 500A (here, the metal oxide 230, the insulator 250, and the conductor 260).

The transistor 500A has a structure where the channel formation region surrounds the gate electrode. Thus, it can be said that the transistor 500A is a transistor having a CAA (Channel-All-Around) structure.

Note that although FIG. 22D illustrates a configuration where a top surface shape of the opening included in the conductor 242 has a circular shape, the present invention is not limited thereto. For example, the top surface shape of the opening included in the conductor 242 may be an elliptical shape, a polygonal shape, or a polygonal shape with rounded corners. Here, the polygonal shape refers to a triangle, a rectangle, a pentagon, a hexagon, or the like. The insulator 250 may have either a single-layer structure or a stacked-layer structure.

For example, silicon oxide, silicon oxynitride, silicon oxide to which fluorine is added, silicon oxide to which carbon is added, silicon oxide to which carbon and nitrogen are added, porous silicon oxide, or the like can be used for the insulator 250. In particular, silicon oxide and silicon oxynitride are preferable because they are thermally stable. In that case, the insulator 250 is an insulator that includes at least oxygen and silicon.

The concentration of impurities such as water and hydrogen in the insulator 250 is preferably reduced.

Note that an insulator having a barrier property against oxygen may be provided between the insulator 250 and the metal oxide 230. The insulator is provided in contact with a bottom surface of the insulator 250 and the depressed portion of the metal oxide 230. When the insulator has a barrier property against oxygen, oxygen included in the insulator 250 can be supplied to the channel formation region, which can inhibit excessive supply of oxygen included in the insulator 250 to the channel formation region. Thus, when heat treatment or the like is performed, release of oxygen from the metal oxide 230 can be inhibited, which can inhibit formation of oxygen vacancies in the metal oxide 230. Accordingly, the transistor 500A can have favorable electrical characteristics and higher reliability.

An insulator including an oxide of one or both aluminum and hafnium is preferably used as the insulator. Aluminum oxide, hafnium oxide, an oxide including aluminum and hafnium (hafnium aluminate), an oxide including hafnium and silicon (hafnium silicate), or the like can be used for the insulator. Aluminum oxide is further preferably used for the insulator. In that case, the insulator is an insulator that includes at least oxygen and aluminum. Note that the insulator, for example, does not easily transmit oxygen compared with the insulator 250. In addition, for example, a material that does not easily transmit oxygen compared with the insulator 250 is used for the insulator. For example, magnesium oxide, gallium oxide, gallium zinc oxide, indium gallium zinc oxide, or the like may be used for the insulator.

FIG. 22B illustrates a single-layer configuration of the conductor 260. Note that the conductor 260 may have a stacked-layer structure. For example, the conductor 260 preferably includes a first conductor and a second conductor over the first conductor. Specifically, the first conductor of the conductor 260 is preferably placed to cover a bottom surface and side surfaces of the second conductor of the conductor 260.

For the first conductor of the conductor 260, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like). Alternatively, it is preferable to use a conductive material that is not easily oxidized.

When the first conductor of the conductor 260 has a function of inhibiting diffusion of oxygen, for example, it is possible to inhibit a decrease in conductivity due to oxidation of the second conductor of the conductor 260 by oxygen included in the insulator 250. As a conductive material having a function of inhibiting diffusion of oxygen, for example, titanium, titanium nitride, tantalum, tantalum nitride, ruthenium, ruthenium oxide, or the like is preferably used.

An insulator 283 is provided over the insulator 250. An insulator having a barrier property against hydrogen is preferably used as the insulator 283. This makes it possible to inhibit diffusion of hydrogen into the metal oxide 230 from the outside of the transistor 500A through the insulator 250. Each of a silicon nitride film and a silicon nitride oxide film can be suitably used for the insulator 283 because each of the silicon nitride film and the silicon nitride oxide film releases a small amount of impurities (e.g., water and hydrogen) and has a feature of not easily transmitting oxygen and hydrogen.

The configuration, structure, method, and the like described in this embodiment can be used in combination as appropriate with the configurations, structures, methods, and the like described in the other embodiments, an example, and the like.

### EMBODIMENT 4

In this embodiment, a cross-sectional configuration example of an element layer (a memory layer) including OS transistors provided over an element layer (a driver circuit layer) including stacked Si transistors, which is a configuration applicable to each circuit included in a semiconductor device, is described. In this embodiment, an example of a cross-sectional schematic diagram applicable to a NOSRAM circuit configuration is described.

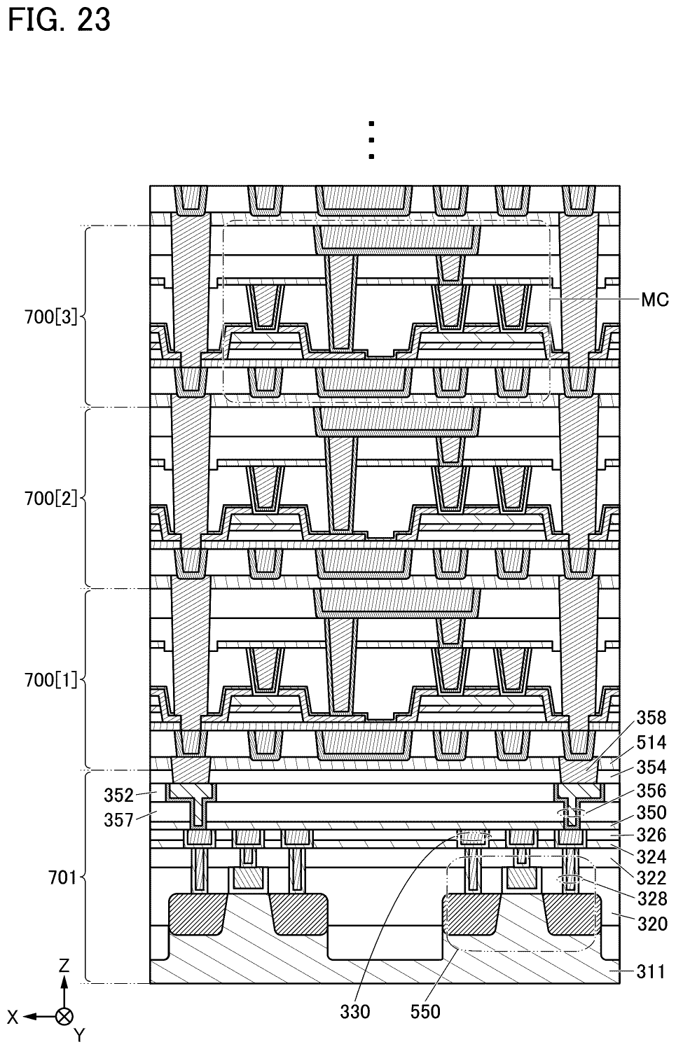

FIG. 23 illustrates a cross-sectional configuration example of the case of using a NOSRAM circuit configuration. In the example illustrated in FIG. 23, an element layer 700[1] to an element layer 700[3] are stacked over an element layer 701. The element layer 701 corresponds to the element layer 50 described in Embodiment 1, and the element layer 700 corresponds to the element layer 40.

FIG. 23 also illustrates an example of the transistor 550 included in the element layer 701. As the transistor 550, the transistor 550 described in the above embodiment can be used.

Note that the transistor 550 illustrated in FIG. 23 is an example and is not limited to the structure illustrated therein; an appropriate transistor can be used in accordance with a circuit configuration or a driving method.

A wiring layer provided with an interlayer film, a wiring, a plug, and the like may be provided between the element layer 701 and the element layers 700 or between a k-th element layer 700 and a (k+1)-th element layer 700. Note that in this embodiment and the like, the k-th element layer 700 is referred to as an element layer 700[k], and the (k+1)-th element layer 700 is referred to as an element layer 700[k+1], in some cases. Here, k is an integer greater than or equal to 1 and less than or equal to N. In addition, in this embodiment and the like, the solutions of “k+α (α is an integer greater than or equal to 1)” and “k−α” are each an integer greater than or equal to 1 and less than or equal to N.

In addition, a plurality of wiring layers can be provided in accordance with design. Furthermore, in this specification and the like, a wiring and a plug electrically connected to the wiring may be a single component. That is, part of a conductor functions as a wiring in some cases, and part of a conductor functions as a plug in other cases.

For example, the insulator 320, the insulator 322, the insulator 324, and the insulator 326 are sequentially stacked and provided over the transistor 550 as interlayer films. In addition, the conductor 328 or the like is embedded in the insulator 320 and the insulator 322. Furthermore, the conductor 330 or the like is embedded in the insulator 324 and the insulator 326. Note that the conductor 328 and the conductor 330 each function as a contact plug or a wiring.

In addition, the insulators functioning as interlayer films may also function as planarization films that cover uneven shapes therebelow. For example, a top surface of the insulator 320 may be planarized by planarization treatment using a chemical mechanical polishing (CMP) method to increase planarity.

A wiring layer may be provided over the insulator 326 and the conductor 330. For example, in FIG. 23, the insulator 350, an insulator 357, the insulator 352, and the insulator 354 are sequentially stacked and provided over the insulator 326 and the conductor 330. Furthermore, the conductor 356 is formed in the insulator 350, the insulator 357, and the insulator 352. The conductor 356 functions as a contact plug or a wiring. The insulator 514 included in the element layer 700[1] is provided over the insulator 354. In addition, a conductor 358 is embedded in the insulator 514 and the insulator 354. The conductor 358 functions as a contact plug or a wiring. For example, the wiring WBL (or the wiring RBL) and the transistor 550 are electrically connected through the conductor 358, the conductor 356, the conductor 330, and the like.

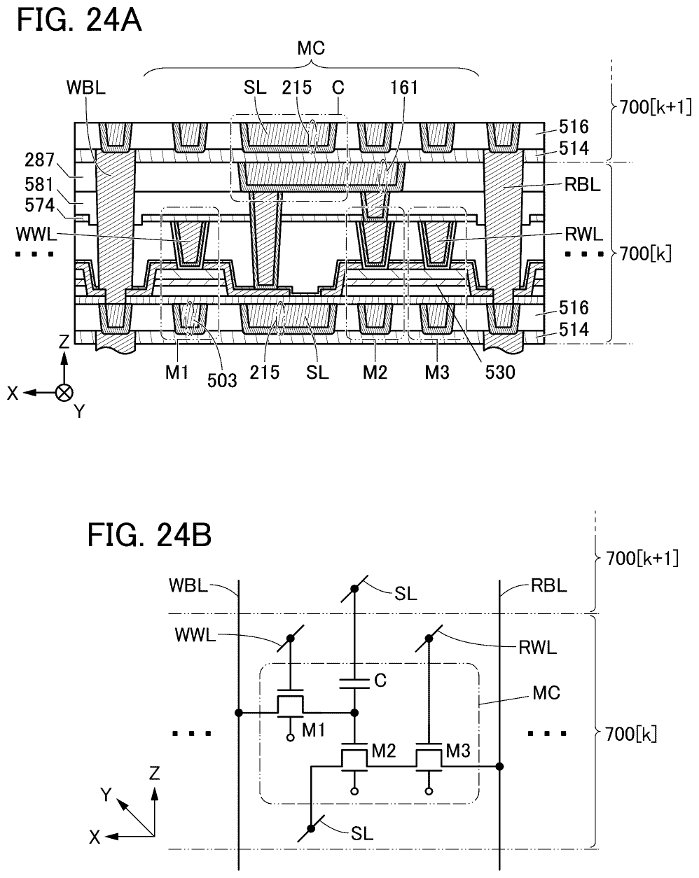

FIG. 24A illustrates a cross-sectional structure example of the element layer 700[k]. In addition, FIG. 24B illustrates an equivalent circuit diagram of FIG. 24A.

The memory cells MC illustrated in FIG. 23 and FIG. 24A each include the transistor M1, the transistor M2, and the transistor M3 over the insulator 514. In addition, a conductor 215 is provided over the insulator 514. The conductor 215 can be formed using the same material in the same process as those of the conductor 503 at the same time.

In addition, the transistor M2 and the transistor M3 illustrated in FIG. 23 and FIG.

24A share one island-shaped metal oxide 530. In other words, part of the one island-shaped metal oxide 530 functions as a channel formation region of the transistor M2, and another part thereof functions as a channel formation region of the transistor M3. Furthermore, the source of the transistor M2 and a drain of the transistor M3 are shared, or the drain of the transistor M2 and a source of the transistor M3 are shared. Thus, the area occupied by the transistor M2 and the transistor M3 is smaller than that of the case where the transistor M2 and the transistor M3 are independently provided.

In addition, in each of the memory cells MC illustrated in FIG. 23 and FIG. 24A, an insulator 287 is provided over the insulator 581, and a conductor 161 is embedded in the insulator 287. Furthermore, the insulator 514 of the element layer 700[k+1] is provided over the insulator 287 and the conductor 161.

In FIG. 23 and FIG. 24A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. Furthermore, the other of a source and a drain of the transistor M1 is electrically connected to the conductor 161 through a contact plug, and the gate of the transistor M2 is electrically connected to the conductor 161 through another contact plug.

This embodiment can be implemented in combination with the other embodiments described in this specification as appropriate.

### EMBODIMENT 5

In this embodiment, a transistor including an oxide semiconductor in a channel formation regions (an OS transistor) is described. Note that comparison of an OS transistor with a transistor including silicon in a channel formation region (also referred to as a Si transistor) is briefly described.

### [OS Transistor]

An oxide semiconductor having a low carrier concentration is preferably used for an OS transistor. For example, the carrier concentration in an oxide semiconductor in a channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Furthermore, electric charge captured by the trap states in the oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the impurity concentration in the oxide semiconductor is effective. In addition, in order to reduce the impurity concentration in the oxide semiconductor, it is preferable that the impurity concentration in an adjacent film be also reduced. Examples of impurities include hydrogen and nitrogen. Note that impurities in an oxide semiconductor refer to, for example, elements other than main components of the oxide semiconductor. For example, an element having a concentration lower than 0.1 atomic % can be regarded as an impurity.

In addition, the OS transistor is likely to change its electrical characteristics when impurities and oxygen vacancies exist in the channel formation region in the oxide semiconductor, which might worsen reliability. In some cases, the OS transistor has a defect that is an oxygen vacancy in the oxide semiconductor into which hydrogen enters (hereinafter sometimes referred to as VoH), which generates an electron serving as a carrier. Furthermore, formation of VoH in the channel formation region might increase the donor concentration in the channel formation region. An increase in the donor concentration in the channel formation region might lead to a variation in threshold voltage. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Therefore, impurities, oxygen vacancies, and VoH are preferably reduced as much as possible in the channel formation region in the oxide semiconductor.

Furthermore, the bandgap of the oxide semiconductor is preferably wider than the bandgap of silicon (typically 1.1 eV), further preferably wider than or equal to 2 eV, still further preferably wider than or equal to 2.5 eV, yet still further preferably wider than or equal to 3.0 eV. With the use of an oxide semiconductor having a wider bandgap than silicon, the off-state current (also referred to as Ioff) of the transistor can be reduced.

Moreover, in a Si transistor, a short-channel effect (also referred to as an SCE) appears as miniaturization of the transistor proceeds. Thus, it is difficult to miniaturize the Si transistor. One factor in causing the short-channel effect is a narrow bandgap of silicon. In contrast, the OS transistor uses an oxide semiconductor that is a semiconductor material having a wide bandgap, and thus can suppress the short-channel effect. In other words, the OS transistor is a transistor where the short-channel effect does not appear or hardly appears.

Note that the short-channel effect refers to degradation of electrical characteristics that becomes obvious along with miniaturization of a transistor (a decrease in channel length). Specific examples of the short-channel effect include a decrease in threshold voltage, an increase in a subthreshold swing value (sometimes referred to as an S value), and an increase in leakage current. Here, the S value refers to the amount of change in gate voltage which makes drain current change by one digit in a subthreshold region at constant drain voltage.

In addition, characteristic length is widely used as an indicator of resistance to a short-channel effect. The characteristic length is an indicator of the curvature of a potential in a channel formation region. The smaller the characteristic length is, the more steeply the potential rises, which means that smaller characteristic length has higher resistance to the short-channel effect.

The OS transistor is an accumulation-type transistor, and the Si transistor is an inversion-type transistor. Thus, the OS transistor has shorter characteristic length between a source region and the channel formation region and shorter characteristic length between a drain region and the channel formation region than the Si transistor. Accordingly, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, the OS transistor can be more suitably used as a short-channel transistor than the Si transistor. Note that the gate length refers to the length of a gate electrode in a direction in which carriers move inside a channel formation region during operation of a transistor, which corresponds to the width of a bottom surface of the gate electrode in a plan view of the transistor.

In addition, miniaturization of the OS transistor can improve the high-frequency characteristics of the transistor. Specifically, the cutoff frequency of the transistor can be improved. When the gate length of the OS transistor is within any of the above ranges, the cutoff frequency of the transistor can be made higher than or equal to 50 GHz, preferably higher than or equal to 100 GHz, further preferably higher than or equal to 150 GHz in a room temperature environment, for example.

As described above, the OS transistor has advantageous effects such as low off-state current and capability of being manufactured with short channel length compared with the Si transistor.

The configuration, structure, method, and the like described in this embodiment can be used in combination as appropriate with the configurations, structures, methods, and the like described in the other embodiments and the like.

### EMBODIMENT 6

This embodiment describes an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device according to one embodiment of the present invention are effective in achieving high performance, e.g., reducing power consumption.

### [Electronic Component]

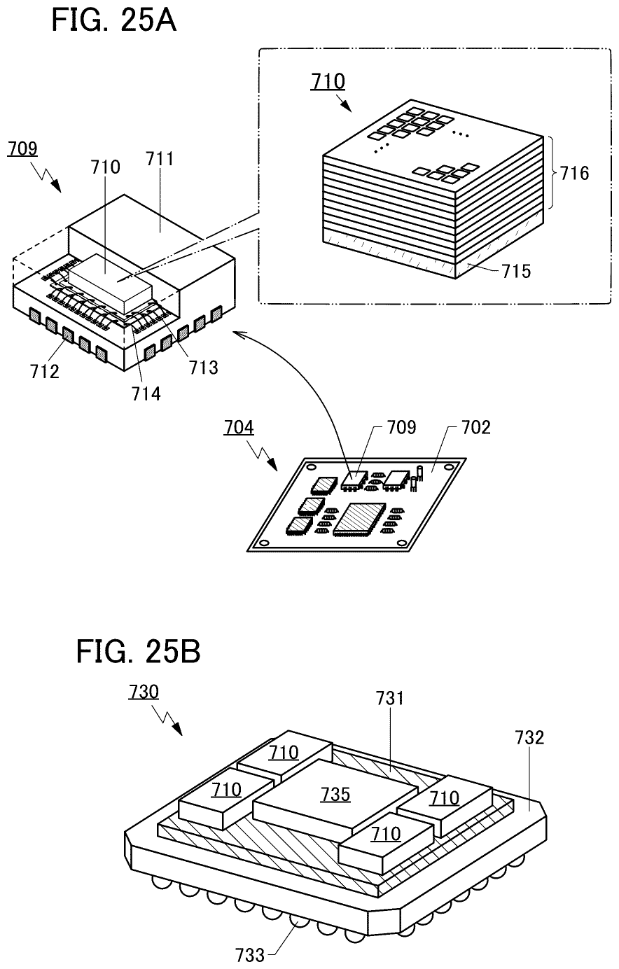

FIG. 25A illustrates a perspective view of a substrate (a mount board 704) on which an electronic component 709 is mounted. The electronic component 709 illustrated in FIG.

25A includes a semiconductor device 710 in a mold 711. FIG. 25A omits illustrations of some parts to show the inside of the electronic component 709. The electronic component 709 includes lands 712 outside the mold 711. The land 712 is electrically connected to an electrode pad 713, and the electrode pad 713 is electrically connected to the semiconductor device 710 via a wire 714. The electronic component 709 is mounted on a printed circuit board 702, for example. A plurality of such electronic components are combined and electrically connected on the printed circuit board 702, so that the mount board 704 is completed.

In addition, the semiconductor device 710 includes a driver circuit layer 715 and an element layer 716. Note that the element layer 716 has a configuration where a plurality of memory cell arrays are stacked. A stacked-layer configuration of the driver circuit layer 715 and the element layer 716 can be a monolithic stacked-layer configuration. In the monolithic stacked-layer configuration, layers can be connected without using a through electrode technique such as a TSV (Through Silicon Via) and a bonding technique such as Cu—Cu direct bonding. The monolithic stacked-layer configuration of the driver circuit layer 715 and the element layer 716 enables, for example, what is called an on-chip memory configuration where a memory is directly formed on a processor. The on-chip memory configuration allows an interface portion between the processor and the memory to operate at high speed.

In addition, with the on-chip memory configuration, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

Furthermore, it is preferable that the plurality of memory cell arrays included in the element layer 716 be formed using OS transistors and be monolithically stacked. The monolithic stacked-layer configuration of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the element layer 716, the monolithic stacked-layer configuration is difficult to form as compared with the case where OS transistors are used for the element layer 716.

Therefore, the OS transistors are superior to the Si transistors in the monolithic stacked-layer configuration.

Moreover, the semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 25B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. In addition, the semiconductor device 735 can be used for an integrated circuit such as a CPU (Central Processing Unit), a GPU (Graphics Processing Unit), or an FPGA (Field Programmable Gate Array). As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate.” Furthermore, a through electrode is provided in the interposer 731 and the through electrode is used to electrically connect an integrated circuit and the package substrate 732 in some cases. Moreover, in a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity, and poor connection between the silicon interposer and an integrated circuit provided on the silicon interposer does not easily occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving wide memory bandwidth. For this reason, the monolithic stacked-layer configuration using the OS transistors is suitable, as described above. A composite structure where memory cell arrays stacked using a TSV and monolithically stacked memory cell arrays are combined may be employed.

In addition, a heat sink (a radiator plate) may be provided to overlap the electronic component 730. In the case where a heat sink is provided, the heights of integrated circuits provided on the interposer 731 are preferably aligned with each other. For example, in the electronic component 730 described in this embodiment, the heights of the semiconductor devices 710 and the semiconductor device 735 are preferably aligned with each other.

Electrodes 733 may be provided on a bottom portion of the package substrate 732 to mount the electronic component 730 on another substrate. FIG. 25B illustrates an example where the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

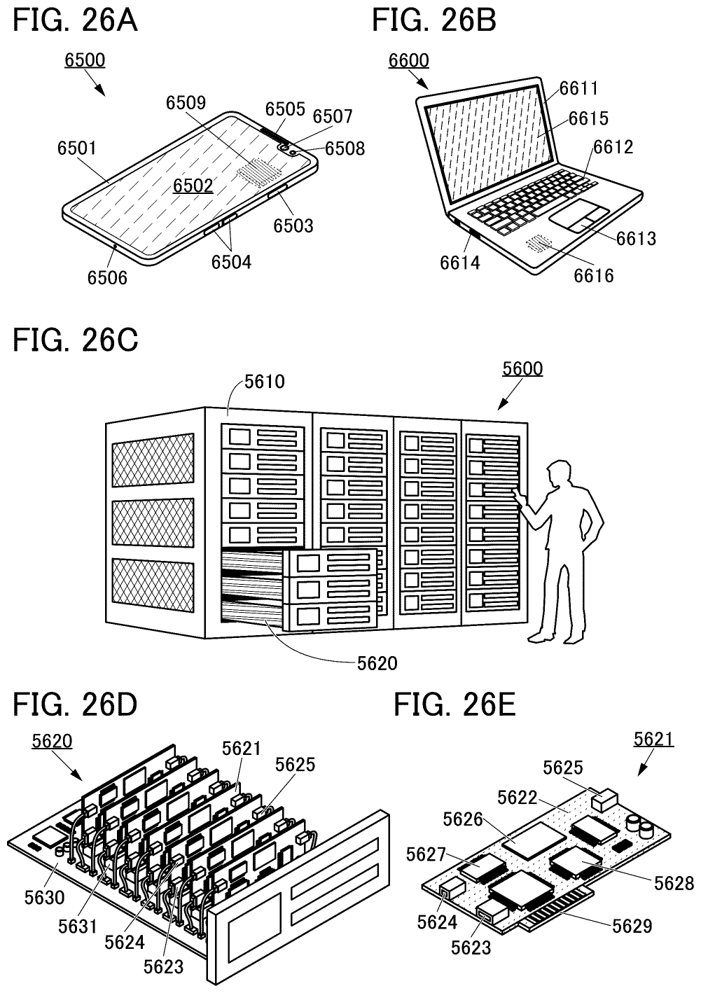

Next, FIG. 26A illustrates a perspective view of an electronic device 6500. The electronic device 6500 illustrated in FIG. 26A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device according to one embodiment of the present invention can be employed for the display portion 6502, the control device 6509, or the like.

An electronic device 6600 illustrated in FIG. 26B is an information terminal that can be used for a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device according to one embodiment of the present invention can be employed for the display portion 6615, the control device 6616, or the like. Note that the semiconductor device according to one embodiment of the present invention is suitably used for each of the control device 6509 and the control device 6616 because power consumption can be reduced.

### [Large Computer]

Next, FIG. 26C illustrates a perspective view of a large computer 5600. In the large computer 5600 illustrated in FIG. 26C, a plurality of rack mount computers 5620 are stored in a rack 5610. Note that the large computer 5600 may also be referred to as a supercomputer.

The computer 5620 can have a configuration in a perspective view illustrated in FIG. 26D, for example. In FIG. 26D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629.

Note that FIG. 26E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a memory device. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device according to one embodiment of the present invention can be suitably used for space equipment such as equipment that processes and stores information.

The semiconductor device according to one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space.

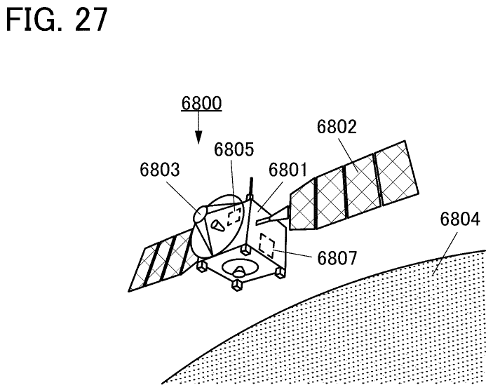

FIG. 27 illustrates an artificial satellite 6800 as an example of space equipment. The artificial satellite 6800 includes a body 6801, solar panels 6802, an antenna 6803, a secondary battery 6805, and a control device 6807. Note that FIG. 27 illustrates a planet 6804 in outer space, for example. Note that outer space refers to, for example, space at an altitude greater than or equal to 100 km, and outer space described in this specification may include the thermosphere, the mesosphere, and the stratosphere.

In addition, although not illustrated in FIG. 27, a battery management system (also referred to as a BMS) or a battery control circuit may be provided in the secondary battery 6805. An OS transistor is suitably used in the battery management system or the battery control circuit because low power consumption and high reliability even in outer space are achieved.

Furthermore, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

In addition, the control device 6807 has a function of controlling the artificial satellite 6800. The control device 6807 is formed using one or more selected from a CPU, a GPU, and a memory device, for example. Note that the semiconductor device according to one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

Alternatively, the artificial satellite 6800 can include a sensor. For example, when the artificial satellite 6800 includes a visible light sensor, the artificial satellite 6800 can have a function of detecting sunlight reflected by a ground-based object. Alternatively, when the artificial satellite 6800 includes a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is illustrated as an example of space equipment in this embodiment, the present invention is not limited thereto. The semiconductor device according to one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### [Data Center]

The semiconductor device according to one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device according to one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device according to one embodiment of the present invention can achieve a data center that stably operates even in a high-temperature environment. Thus, the reliability of the data center can be increased.

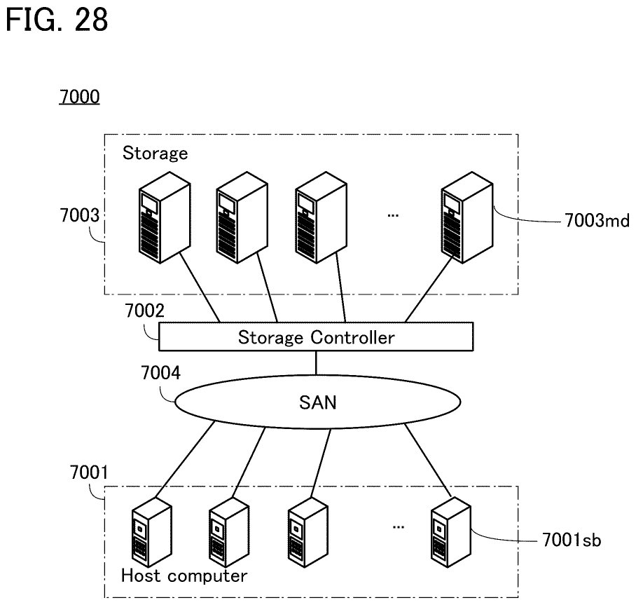

FIG. 28 illustrates a storage system applicable to a data center. A storage system 7000 illustrated in FIG. 28 includes a plurality of servers 7001sb as a host 7001 (indicated as “Host Computer” in the diagram). In addition, the storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device according to one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device according to one embodiment of the present invention. Furthermore, the semiconductor device according to one embodiment of the present invention has low power consumption and thus is effective as a global warming countermeasure.

The composition, structure, method, and the like described in this embodiment can be used in combination as appropriate with the compositions, structures, methods, and the like described in the other embodiments and the like.

(Supplementary Notes on the Description in this Specification and the Like)

The description of the above embodiments and each configuration in the embodiments are noted below.

One embodiment of the present invention can be constituted by combining, as appropriate, the configuration described in each embodiment with the configurations described in the other embodiments. In addition, in the case where a plurality of configuration examples are described in one embodiment, the configuration examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation. Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor.

This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an ON state) or a non-conduction state (an OFF state). Alternatively, a switch has a function of selecting and changing a current path.

In this specification and the like, channel length refers to, for example, the distance between a source and a drain in a region where a semiconductor (or a portion where current flows in a semiconductor when a transistor is in an ON state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an ON state) and a gate electrode overlap each other or a region where a channel is formed.

In this specification and the like, a node can be referred to as a terminal, a wiring, an electrode, a conductive layer, a conductor, an impurity region, or the like depending on a circuit configuration, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### REFERENCE NUMERALS

10: semiconductor device, 40: element layer, 41: memory cell portion, 42: memory cell, 43:

memory cell array, 50: element layer, 51: write word line driver circuit, 52: read word line driver circuit, 53: write bit line driver circuit, 54: read bit line driver circuit, 55: arithmetic circuit, 56: arithmetic control circuit, and 57: control circuit.

1. A semiconductor device comprising:
a first element layer comprising a bit line driver circuit;
a second element layer over the first element layer, the second element layer comprising a first switch circuit, a first memory cell, and a first wiring provided between the first switch circuit and the first memory cell; and
a third element layer over the second element layer, the third element layer comprising a second switch circuit, a second memory cell, and a second wiring provided between the second switch circuit and the second memory cell,
wherein the second element layer overlaps the first element layer,
wherein the third element layer overlaps the second element layer,
wherein the second element layer and the third element layer are provided with a third wiring electrically connected to the bit line driver circuit,
wherein the bit line driver circuit is electrically connected to the first switch circuit and the second switch circuit through the third wiring,
wherein the first switch circuit is configured to establish a non-conduction state between the first wiring and the third wiring in one of data write operation and data read operation of the second memory cell, and
wherein the second switch circuit is configured to establish a non-conduction state between the second wiring and the third wiring in one of data write operation and data read operation of the first memory cell.

2. The semiconductor device according to claim 1, wherein the second element layer and the third element layer are each provided with a transistor including a channel formation region comprising an oxide semiconductor.

3. The semiconductor device according to claim 2, wherein the oxide semiconductor comprises In, Ga, and Zn.

4. The semiconductor device according to claim 1, wherein the first element layer is provided with a transistor including a channel formation region comprising silicon.

5. The semiconductor device according to claim 1,
wherein the first switch circuit is configured to pre-charge a potential of the first wiring, and
wherein the second switch circuit is configured to pre-charge a potential of the second wiring.

6. The semiconductor device according to claim 1,
wherein the first element layer comprises an arithmetic circuit being configured to perform arithmetic processing based on data read to the bit line driver circuit, and
wherein the arithmetic circuit is provided in a region overlapping the first memory cell included in the second element layer and the second memory cell included in the third element layer.

7. The semiconductor device according to claim 1, wherein the third wiring comprises a portion extending along a direction perpendicular to the first element layer.

8. A semiconductor device comprising:
a first element layer comprising a word line driver circuit and a bit line driver circuit;
a second element layer over the first element layer, the second element layer comprising a first switch circuit, a first layer selection circuit, a first memory cell, a first wiring provided between the first switch circuit and the first memory cell, and a second wiring provided between the first layer selection circuit and the first memory cell; and
a third element layer over the second element layer, the third element layer comprising a second switch circuit, a second layer selection circuit, a second memory cell, a third wiring provided between the second switch circuit and the second memory cell, and a fourth wiring provided between the second layer selection circuit and the second memory cell,
wherein the second element layer overlaps the first element layer,
wherein the third element layer overlaps the second element layer,
wherein the second element layer and the third element layer are provided with a fifth wiring electrically connected to the bit line driver circuit and a sixth wiring electrically connected to the word line driver circuit,
wherein the bit line driver circuit is electrically connected to the first switch circuit and the second switch circuit through the fifth wiring,
wherein the word line driver circuit is electrically connected to the first layer selection circuit and the second layer selection circuit through the sixth wiring,
wherein the first switch circuit is configured to establish a non-conduction state between the first wiring and the fifth wiring in one of data write operation and data read operation of the second memory cell,
wherein the second switch circuit is configured to establish a non-conduction state between the third wiring and the fifth wiring in one of data write operation and data read operation of the first memory cell, and
wherein the first layer selection circuit and the second layer selection circuit are each configured to output, to one of the second wiring and the fourth wiring, a signal output from the word line driver circuit.

9. The semiconductor device according to claim 8, wherein the second element layer and the third element layer are each provided with a transistor including a channel formation region comprising an oxide semiconductor.

10. The semiconductor device according to claim 9, wherein the oxide semiconductor comprises In, Ga, and Zn.

11. The semiconductor device according to claim 8, wherein the first element layer is provided with a transistor including a channel formation region comprising silicon.

12. The semiconductor device according to claim 8,
wherein the first switch circuit is configured to pre-charge a potential of the first wiring, and
wherein the second switch circuit is configured to pre-charge a potential of the third wiring.

13. The semiconductor device according to claim 8, wherein the first element layer comprises an arithmetic circuit being configured to perform arithmetic processing based on data read to the bit line driver circuit, and
wherein the arithmetic circuit is provided in a region overlapping the first memory cell included in the second element layer and the second memory cell included in the third element layer.

14. The semiconductor device according to claim 8,
wherein the fifth wiring and the sixth wiring each comprise a portion extending along a direction perpendicular to the first element layer.
